(19) United States
(12) Patent Application Publication
(10) Pub. No.: US 2026/0371698 A1
(43) Pub. Date: Nov. 19, 2026

(54) NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Kuan-Ting Pan, Taipei City (TW); Kuo-Cheng Chiang, Zhubei City (TW); Chih-Hao Wang, Baoshan Township (TW)

(21) Appl. No.: 19/751,991

(22) Filed: Jul. 23, 2026

Related U.S. Application Data
(63) Continuation of application No. 19/045,201, filed on Feb. 4, 2025.
(60) Provisional application No. 63/690,147, filed on Sep. 3, 2024.

(51) Int. Cl. H10D 84/01; H10D 64/01; H10D 84/83

(52) U.S. Cl. CPC H10D 84/0151; H10D 64/017; H10D 84/0135; H10D 84/832

(57) ABSTRACT

During formation of a nanostructure field-effect transistor (NSFET) device, a dielectric wall is used to cut the replacement gate structure into separate replacement gate structures. The dielectric wall may be formed by replacing a portion of the replacement gate structure disposed between two adjacent fins/channel stacks/stacked nanostructures with one or more dielectric materials. The dielectric wall reduces the size of the replacement gate structure, thereby reducing the gate-source capacitance (e.g., a parasitic capacitance), which in turn reduces the RC delay and the power consumption of the device formed. Due to the self-aligned manner of formation for the dielectric wall, the distance between adjacent fins/channel stacks/stacked nanostructures can be scaled down further to achieve higher level of integration.

### PRIORITY CLAIM AND CROSS-REFERENCE

This application is a continuation of U.S. patent application Ser. No. 19/045,201, filed Feb. 4, 2025 and entitled “Nanostructure Field-Effect Transistor Device and Methods of Forming,” which application claims priority to U.S. Provisional Application No. 63/690,147, filed Sep. 3, 2024 and entitled “Cut PO Fork-Sheet with Top Dielectric Layer by Alternative Flow with Layout Design Flexibility to Achieve Both Device Performance Gain and Density Scaling,” which applications are incorporated herein by reference.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, 16A, 16B, 17A, 17B, 18A, 18B, 19A, 19B, 19C, 20A, 20B, 20C, 21A, 21B, 21C, 21D, 21E, and 21F are various views of a portion of a nanostructure field-effect transistor (NSFET) device at various stages of manufacturing, in accordance with an embodiment.

FIGS. 22A and 22B are various views of a portion of an NSFET device, in accordance with another embodiment.

FIG. 23 is a cross-sectional view of a portion of an NSFET device, in accordance with another embodiment.

FIG. 24 is a cross-sectional view of a portion of an NSFET device, in accordance with another embodiment.

FIGS. 25, 26A, and 26B are cross-sectional views of a portion of an NSFET device at various stages of manufacturing, in accordance with another embodiment.

FIGS. 27 and 28 are cross-sectional views of a portion of an NSFET device at various stages of manufacturing, in accordance with another embodiment.

FIG. 29 is a cross-sectional view of a portion of an NSFET device, in accordance with another embodiment.

FIG. 30 is a cross-sectional view of a portion of an NSFET device, in accordance with another embodiment.

FIG. 31 is a cross-sectional view of a portion of an NSFET device, in accordance with yet another embodiment.

FIGS. 32A and 32B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

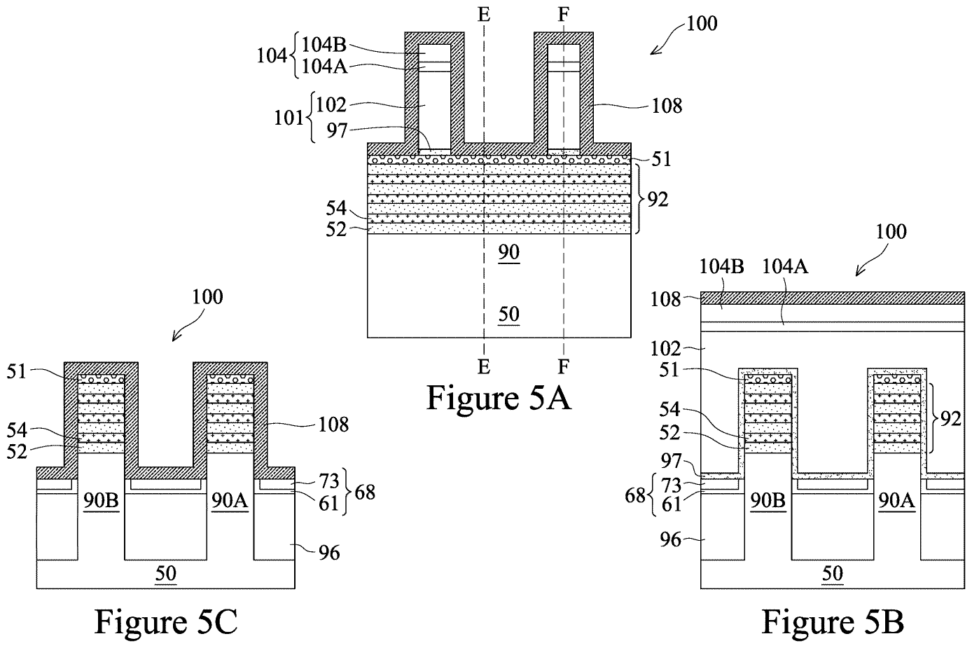

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same numeral but different alphabets (e.g., FIG. 5A-5C) illustrate different views of the device at the same stage of processing.

In some embodiments, during formation of a nanostructure field-effect transistor (NSFET) device, a dielectric wall is used to cut the replacement gate structure into separate replacement gate structures. The dielectric wall may be formed by replacing a portion of the replacement gate structure disposed between two adjacent fins/channel stacks/stacked nanostructures with one or more dielectric materials. The dielectric wall reduces the size of the replacement gate structure, thereby reducing the gate-source capacitance (e.g., a parasitic capacitance), which in turn reduces the RC delay and the power consumption of the device formed. Due to the self-aligned manner of formation for the dielectric wall, the distance between adjacent fins/channel stacks/stacked nanostructures can be scaled down further to achieve higher level of integration. In addition to the dielectric wall, dummy sheets may be formed over the nanostructures. The dummy sheets provide a reference point for a controlled removal process to reduce the height of the replacement gate structure, which further reduces the gate-source capacitance. The dummy sheets also ensure a uniform thickness for the work function material of the replacement gate structures to achieve a uniform threshold voltage for the device formed.

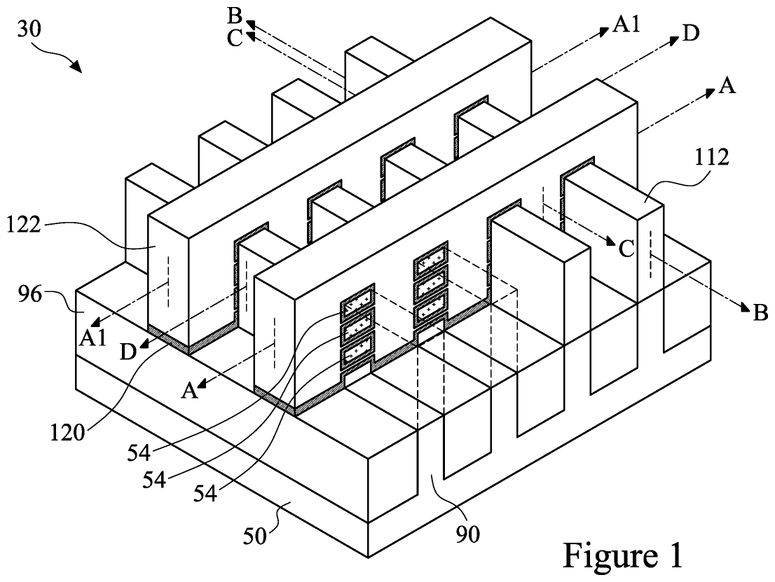

FIG. 1 illustrates an example of a nanostructure field-effect transistor (NSFET) device 30 in a three-dimensional view, in accordance with some embodiments. The NSFET device 30 comprises semiconductor fins 90 (also referred to as fins, protrusions, or base portions) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section A1-A1 is along a longitudinal axis of an adjacent gate electrode 122. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

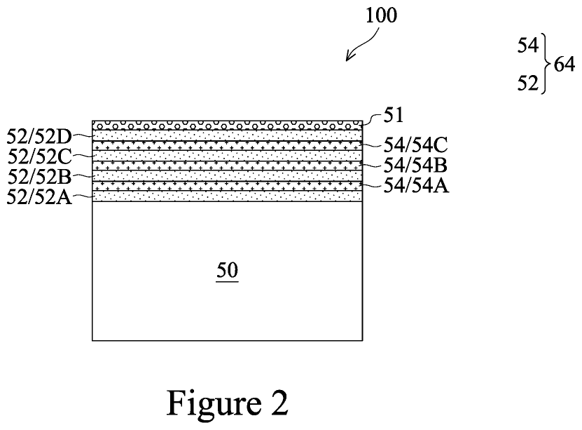

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, 16A, 16B, 17A, 17B, 18A, 18B, 19A, 19B, 19C, 20A, 20B, 20C, 21A, 21B, 21C, 21D, 21E, and 21F are various views (e.g., cross-sectional view, top view) of a portion of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, 52C, and 52D, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure. For example, the number of layers of the second semiconductor material 54 may be between two and four.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple horizontally extending nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

In the example of FIG. 2, a dielectric material 51 (may also be referred to as a top dielectric material 51) is formed on the multi-layer stack 64. The dielectric material 51 may be, e.g., silicon oxide, silicon nitride, silicon carbonitride, silicon oxycarbonitride, a low-K dielectric material, or the like. A suitable deposition method, such as chemical vapor deposition (CVD) or the like, may be used to form the dielectric material 51. In some embodiments, the dielectric material 51 is omitted. The discussion herein uses examples where the dielectric material 51 is formed. Skilled artisans, upon reading the disclosure herein, should be able to readily adapt the processing described herein for embodiments where the dielectric material 51 is omitted.

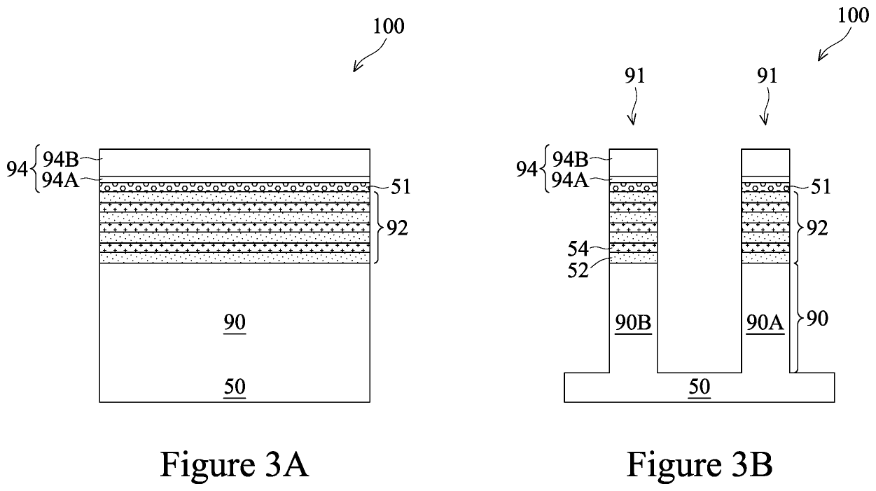

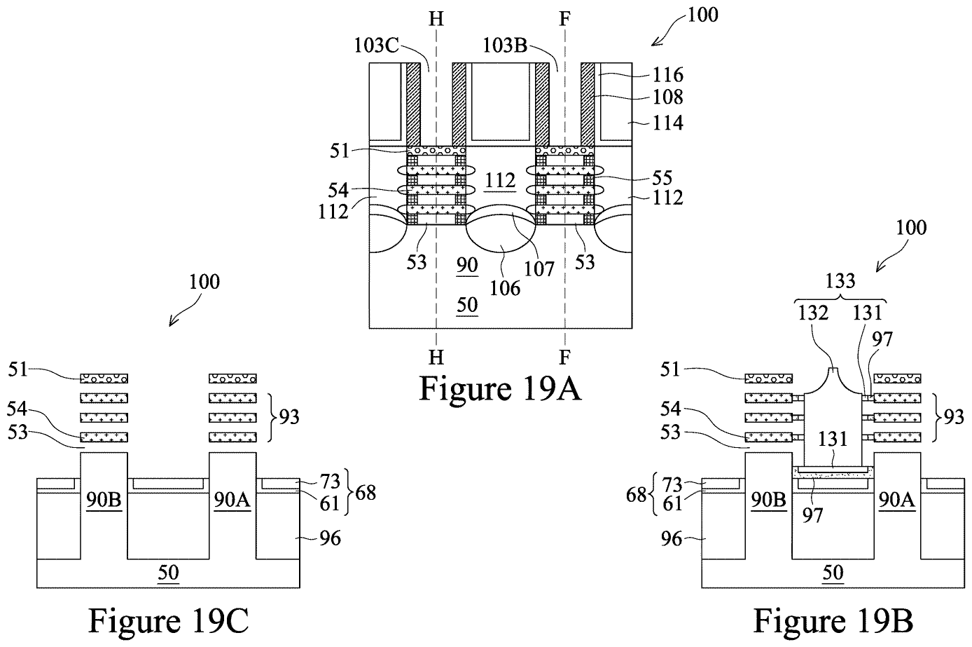

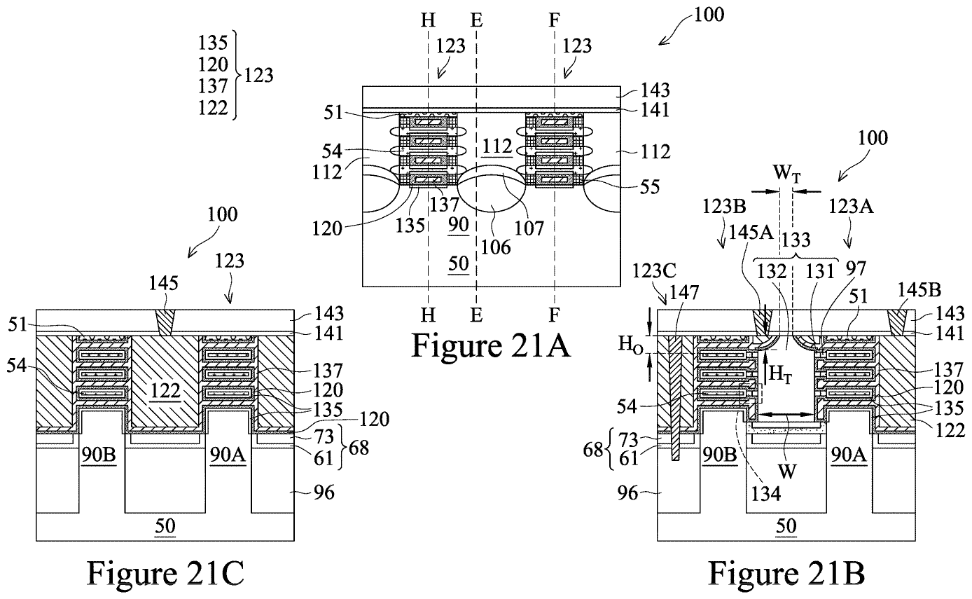

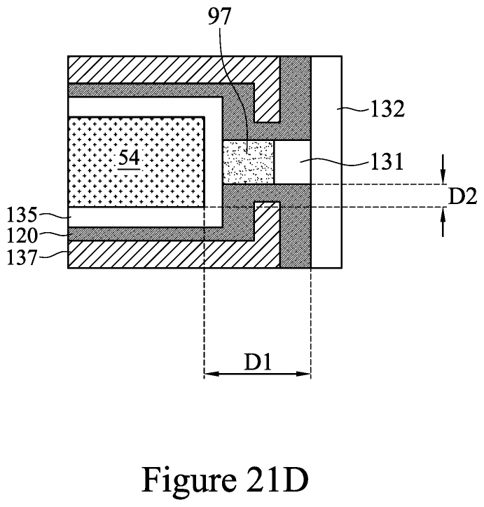

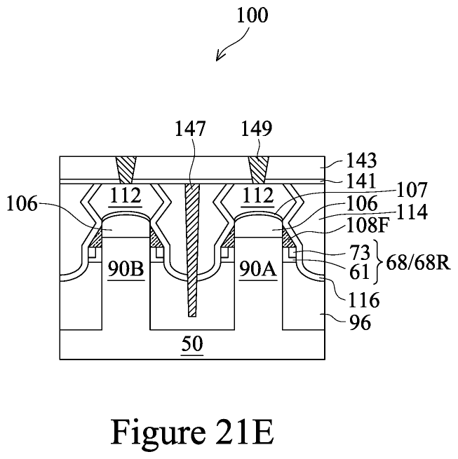

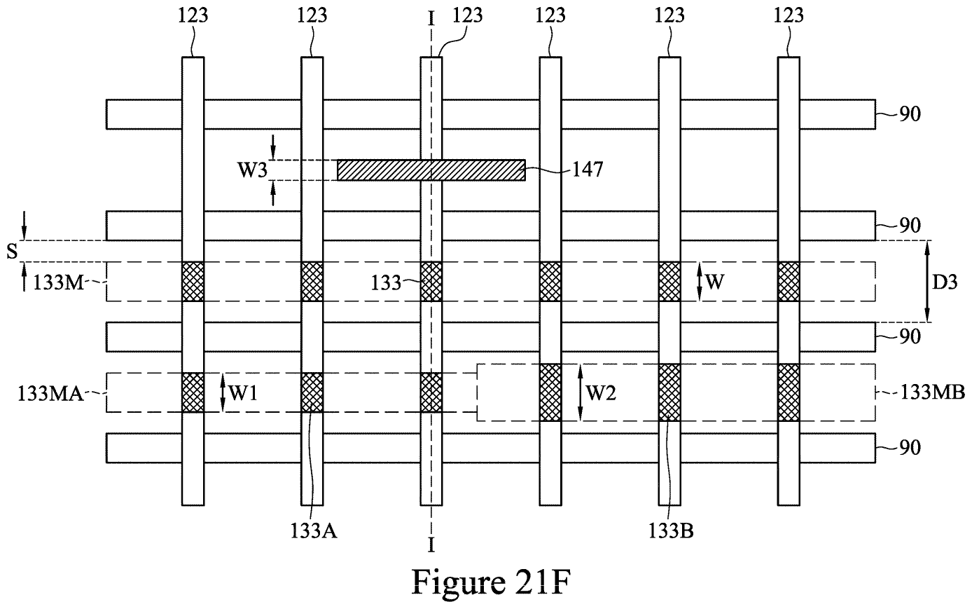

FIGS. 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, 16A, 16B, 17A, 17B, 18A, 18B, 19A, 19B, 19C, 20A, 20B, 20C, 21A, 21B, 21C, 21D, 21E, and 21F are various views (e.g., cross-sectional view, top view) of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, 19A, 20A, and 21A are cross-sectional views along cross-section B-B in FIG. 1. FIGS. 3B, 4B, 5B, 6B, 7B, 8B, 9B, 10B, 11B, 12B, 13B, 14B, 15B, 16B, 17B, 18B, 19B, 20B, and 21B are cross-sectional views along cross-section A-A in FIG. 1. FIG. 21D is a zoomed-in view of a portion of FIG. 21B. FIGS. 19C, 20C, and 21C are cross-sectional views along cross-section A1-A1 in FIG. 1. FIGS. 5C, 6C, 7C, 8C, 9C, 10C, 11C, 12C, and 21E are cross-sectional views along cross-section D-D in FIG. 1. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin), a layer stack 92 overlying the semiconductor fin 90, and a dielectric layer 51 (may also be referred to as a top dielectric layer 51, or a dummy sheet 51) overlying the layer stack 92. The dielectric layer 51, the layer stack 92, and the semiconductor fin 90 may be formed by etching trenches in the dielectric material 51, the multi-layer stack 64, and the substrate 50, respectively. The dielectric layer 51, the layer stack 92, and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50, the multi-layer stack 64, and the dielectric material 51. The etching may be any acceptable etching process, such as a reactive ion etch (RIE), neutral beam etch (NBE), the like, or a combination thereof. The etching is an anisotropic etching process, in some embodiments. After the etching process, the patterned dielectric material 51 forms the dielectric layer 51, the patterned multi-layer stack 64 forms the layer stack 92, and the patterned portion of the substrate 50 forms the fin 90 (e.g., 90A or 90B), as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50, and the dielectric layer 51 is formed of a same material as the dielectric material 51. In the example of FIGS. 3A and 3B, fins 90A and 90B are formed to extend parallel to each other.

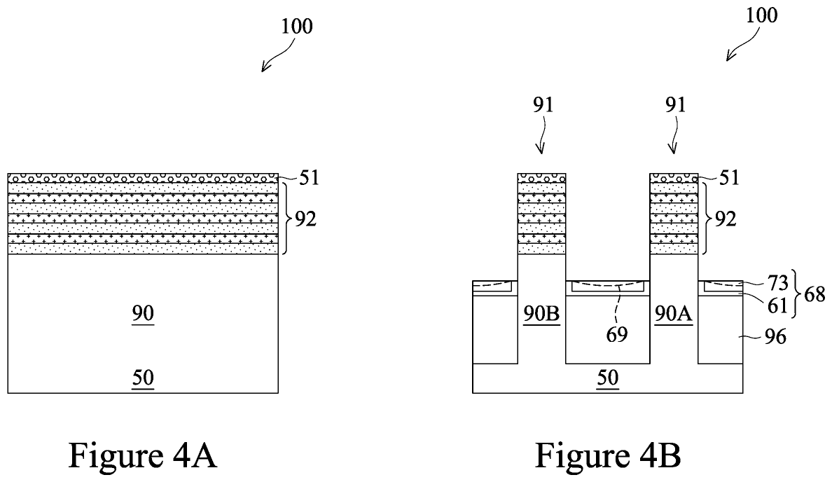

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride such as silicon nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the dielectric layers 51 such that top surfaces of the dielectric layers 51 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, an STI protection structure 68 is formed (e.g. selectively formed) on the upper surfaces of the STI regions 96. The STI protection structure 68 includes a liner layer 61 and a hard mask layer 73, in the illustrated embodiment. In some embodiments, the STI protection structure 68 is formed by depositing a liner layer and a hard mask layer, then patterning the deposited liner layer and hard mask layer, details are discussed below.

In some embodiments, the liner layer 61 is formed over the dummy sheets 51, the layer stacks 92, and the STI regions 96. The liner layer 61 may be a suitable dielectric material such as silicon oxide, and may be formed using a suitable deposition method such as CVD, atomic layer deposition (ALD), or the like. The liner layer 61 protects the layer stacks 92 from damage by subsequent etching process(es) used to form the STI protection structure 68, in some embodiments. The liner layer 61 may also be referred to as an oxide liner layer. Besides silicon oxide, other suitable material, such as a dielectric material that provides high etching selectivity from the layer stack 92 and the subsequently formed hard mask layer 73 may also be used.

The hard mask layer 73 is formed next over the liner layer 61. The hard mask layer 73 is formed of a material different from the liner layer 61 and the STI regions 96. In some embodiments, the material of the hard mask layer 73 is chosen to provide high etching selectivity from the material of the STI regions 96, such that in a subsequent sheet formation process (e.g., an etching process) to form nanostructures (e.g., nanosheets), the hard mask layer 73 protects the STI regions 96 to prevent loss of the STI regions 96. In an embodiment, the STI regions 96 is formed of silicon oxide, and the hard mask layer 73 is formed of silicon nitride. Besides silicon nitride, other suitable materials, such as silicon oxynitride, silicon oxycarbonitride, or the like, may also be used for the hard mask layer 73. A suitable formation method, such as CVD, plasm-enhanced CVD (PECVD), or the like, may be used to form the hard mask layer 73.

Next, a plurality of etching processes are performed to remove the liner layer 61 and the hard mask layer 73 from the exterior surfaces of the dummy sheets 51 and the sidewalls of the layer stack 92. The plurality of etching processes may use various etching masks and/or sacrificial material(s) to shield certain portions of the liner layer 61 and the hard mask layer 73 from the etching processes, in order to achieve a target shape of the STI protection structure 68. After the plurality of etching processes are finished, the remaining portions of the liner layer 61 and the remaining portions of the hard mask layer 73 form the STI protection structure 68. The upper surfaces of the STI protection structure 68 are illustrated as flat surfaces in FIG. 4B as a non-limiting example. The upper surfaces of the STI protection structure 68 may be curved, as illustrated by the dashed lines 69 in FIG. 4B. Besides the illustrated dual-layered structure, the STI protection structure 68 may include a single layer of a dielectric material, or more than two layers of different dielectric materials, these and other variations are fully intended to be included within the scope of the present disclosure.

Next, in FIGS. 5A-5C, a dummy dielectric layer 97 is formed over the STI protection structure 68 and over the sidewalls and the top surfaces of the fin structures 91 and the dummy sheets 51. The dummy dielectric layer 97 may be, for example, silicon oxide, silicon nitride, a combination thereof, or the like, and may be deposited by CVD, ALD, or the like, or may be thermally grown according to acceptable techniques. In an embodiment, a layer of silicon is conformally formed over the dummy sheets 51, the layer stacks 92, and over the upper surface of the STI protection structure 68, and a thermal oxidization process is performed to convert the deposited silicon layer into an oxide layer as the dummy dielectric layer 97.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectric 97. The dummy gate 102 and the underlying dummy gate dielectric 97 may be collectively referred to as a dummy gate structure 101. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91.

Next, a gate spacer layer 108 is formed by conformally depositing an insulating material over the dummy sheets 51, the STI protection structure 68, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections F-F and E-E in FIG. 5A, respectively. The cross-sections E-E and F-F correspond to cross-sections D-D and A-A in FIG. 1, respectively. Note that FIG. 5A illustrates the cross-sectional view along the longitudinal direction (e.g., a current flow direction) of one of the fins 90, the cross-sectional views along the longitudinal directions (e.g., current flow directions) of other fins 90 are the same or similar unless otherwise specified. In addition, FIG. 5A illustrates two dummy gates 102 as a non-limiting example, the number of dummy gates 102 over the fins 90 may be any suitable number.

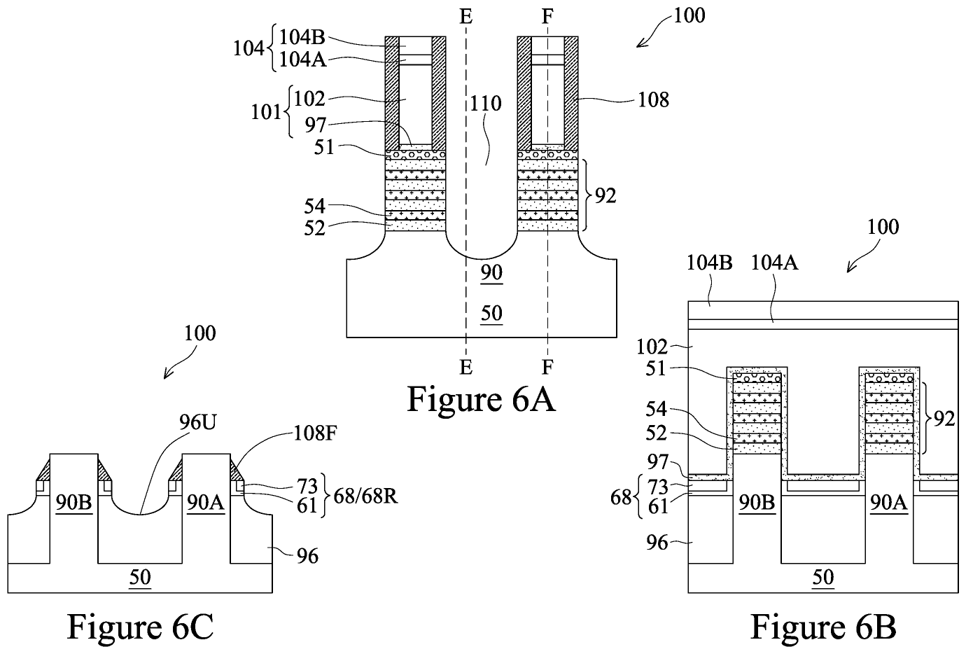

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 along sidewalls of the dummy gate structures 101 forming the gate spacers 108. In addition, the remaining vertical portions of the gate spacer layer 108 along sidewalls of the fins 90 form fin spacers 108F (see FIG. 6C). The anisotropic etching process may also remove horizontal portions of the dielectric layers 51 exposed by (e.g., not covered by) the dummy gate structures 101, and therefore, expose the layer stack 92.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses or source/drain openings) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask. Sidewalls of the openings 110 expose the first semiconductor material 52 and the second semiconductor material 54.

In the example of FIG. 6C, the anisotropic etching process for forming the source/drain openings 110 removes portions of the STI protection structure 68 that are disposed beyond sidewalls of the fin spacers 108F, and also removes portions of the underlying STI regions 96, thereby resulting in recesses in the STI regions 96. FIG. 6C shows curved (e.g., concave) upper surfaces 96U of the STI regions 96 due to the etching of the STI regions 96. Note that portions of the STI protection structure 68 under (e.g., directly under) the dummy gates 102 are shielded from the anisotropic etching process, thus remain intact. In some embodiments, the STI protection structure 68 shields the STI regions 96 from the anisotropic etching process performed for forming the source/drain openings 110, and therefore, no recess is formed in the STI regions 96.

As illustrated in FIG. 6C, portions of the STI protection structure 68 remain under the fin spacers 108F, and are referred to as remaining portions 68R of the STI protection structure 68. The remaining portions 68R of the STI protection structure 68 protect the fins 90 from over-etching by the anisotropic etching process for forming the source/drain openings 110. Without the remaining portions 68R of the STI protection structure 68, over-etching by the anisotropic etching process may expose and/or remove portions of the fins 90 disposed below the fin spacers 108F. The un-intended removal of the portions of the fins 90 by the over-etching may cause the fins 90 to collapse, and/or may cause un-intended growth of epitaxial source/drain material from the un-intendedly exposed portions of the fins 90 during the subsequent source/drain regions formation process. The un-intended growth of epitaxial source/drain material between adjacent fins 90 may cause electrical short between the adjacent source/drain regions, thus causing device failure. The disclosed method herein, by having the remaining portions 68R of the STI protection structure 68, avoids the above over-etching related issues, thereby preventing or reducing the likelyhood of device failure and improving production yield. This illustrates another advantage of the presently disclosure.

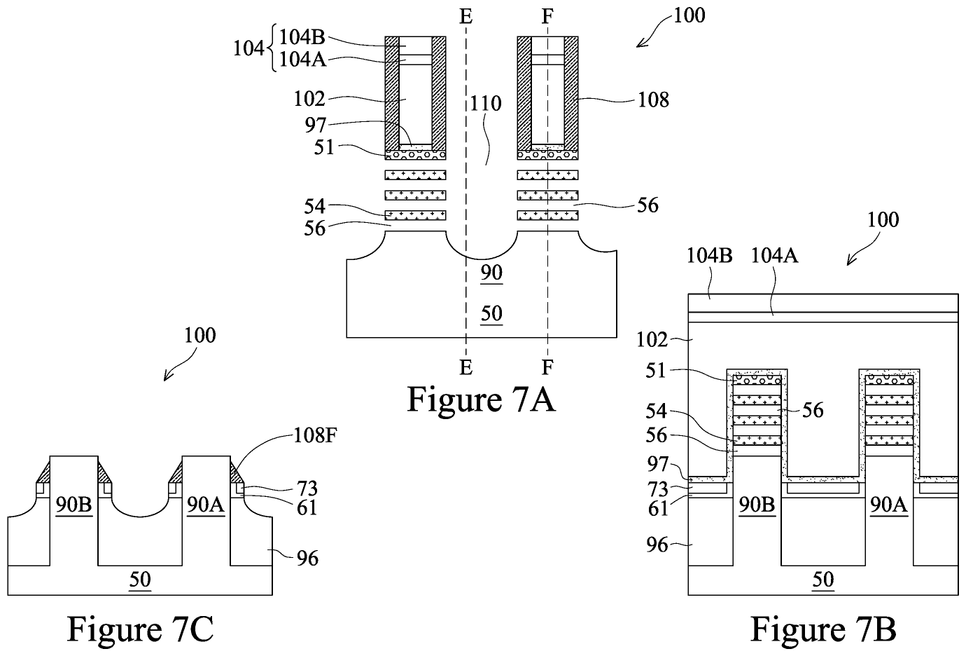

Next, in FIGS. 7A-7C, the first semiconductor material 52 under the dummy gates 102 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, the STI regions 96, and the dummy sheets 51 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, between the dummy sheets 51 and an uppermost layer of the semiconductor material 54, and between the fin 90 and a lowermost layer of the second semiconductor material 54.

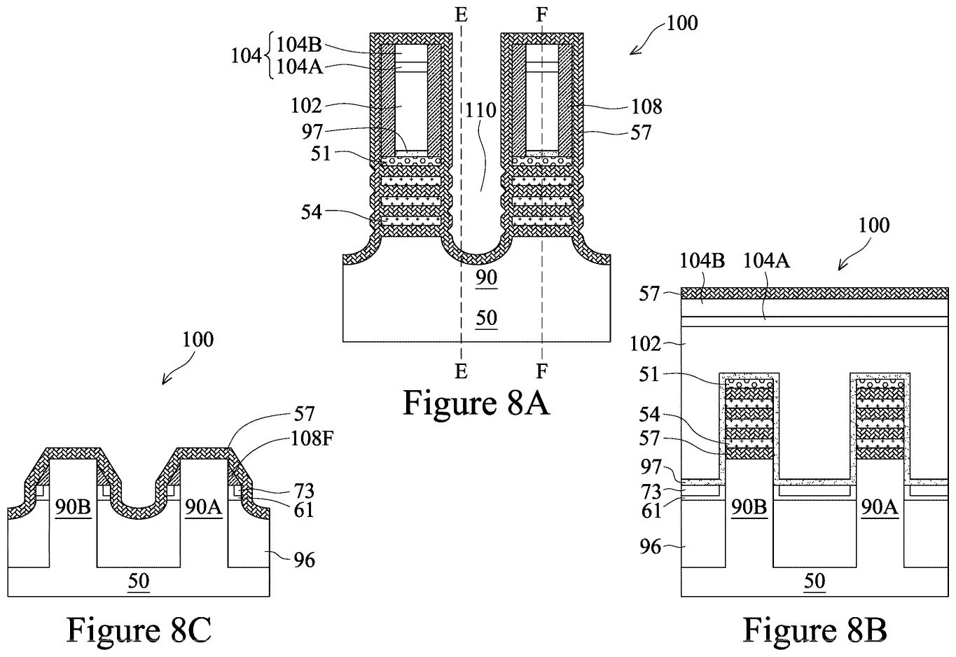

Next, in FIGS. 8A-8C, a disposable material 57 (may also be referred to as a sacrificial material) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 may be a dielectric material. In some embodiments, the disposable material 57 includes one or more layers of silicon oxide (SiO), silicon oxynitride (SiON), aluminum oxide (Al₂O₃), or the like. These materials are selected for their properties, such as etching selectivity, which allows for precise removal during the manufacturing process without adversely affecting the adjacent and underlying structures. The choice of the disposable material 57 may depend on the performance targets of the semiconductor device being fabricated and the targeted electrical and physical properties of the final product.

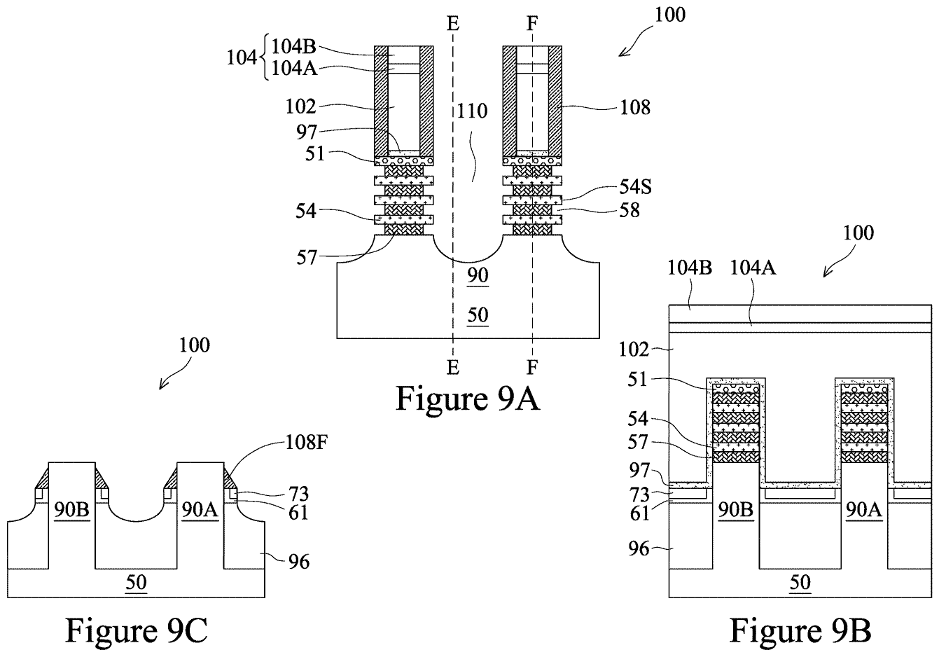

Next, in FIGS. 9A-9C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, between the dummy sheets 51 and an uppermost layer of the semiconductor material 54, or between the fins 90 and a lowermost layer of the second semiconductor material 54, may be referred to as disposable oxide interposers (DOIs). In the subsequent sheet formation process, the DOIs are selectively removed to release the layers of the second semiconductor material 54 to form nanostructures 54 (e.g., nanosheets, or nanowires). This process disclosed herein for forming NSFET devices using DOIs may be referred to as a DOI process for forming NSFET devices.

Replacing the first semiconductor material 52 with the disposable material 57 in the DOI process may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting devices. By replacing the first semiconductor material 52 with the disposable material 57 prior to the high temperature processes (e.g., source/drain annealing), intermixing is avoided, and manufacturing defects can be reduced and device performance can be improved. In addition, the material (e.g., SiO) of the DOIs provides excellent etching selectivity (e.g., higher than 10,000) from the material (e.g. Si) of the second semiconductor material 54, thus allowing for selective removal of the DOIs in the subsequent sheet formation process with little or no damage to the nanostructures 54.

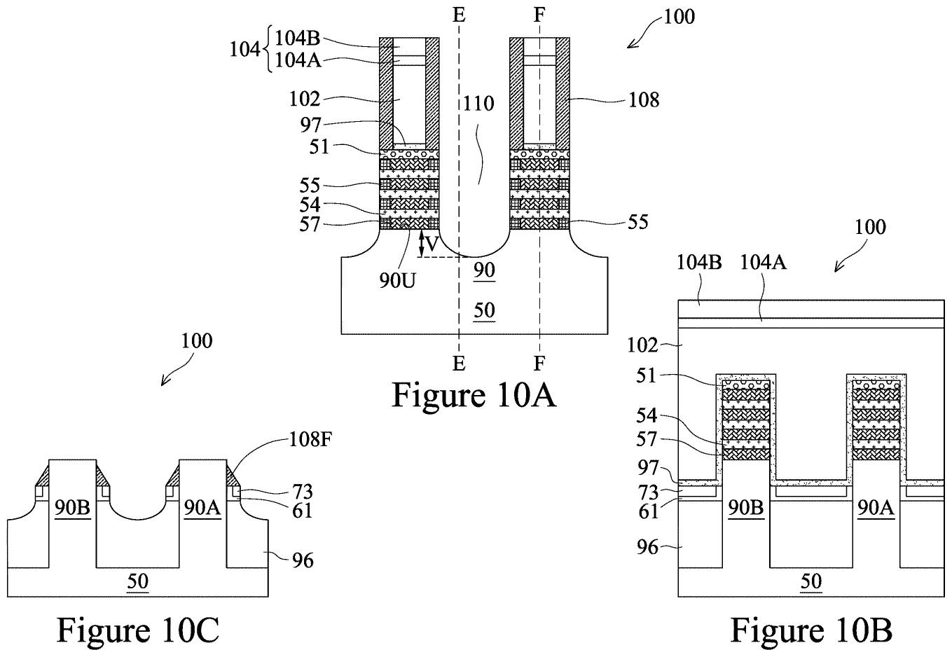

Next, in FIGS. 10A-10C, inner spacers 55 are formed in the sidewall recesses 58. FIGS. 10B and 10C illustrate cross-sectional views of the NSFET device 100 in FIG. 10A along cross-sections F-F and E-E, respectively. In some embodiments, to form the inner spacers 55, an inner spacer layer is formed (e.g., conformally) in the openings 110. The inner spacer layer also fills the sidewall recesses 58 of the sacrificial material 57. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process, such as an anisotropic etching process, is performed to remove portions of the inner spacer layers disposed outside the sidewall recesses 58 of the sacrificial material 57. The remaining portions of the inner spacer layers (e.g., portions disposed inside the sidewall recesses 58 of the sacrificial material 57) form inner spacers 55. As illustrated in FIG. 10A, the openings 110 expose sidewalls of the second semiconductor material 54.

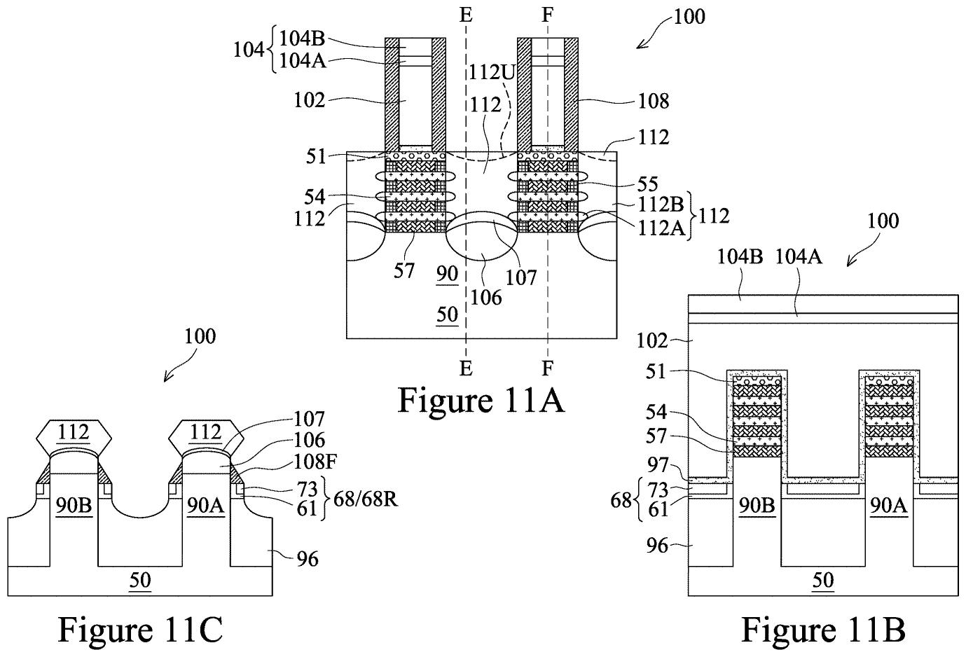

Next, in FIGS. 11A-11C, an un-doped epitaxial material 106 (e.g., epitaxial silicon) is formed at the bottoms of the openings 110, e.g., by an epitaxial growth process. In some embodiments, the vertical offset V (see notation in FIG. 10A) between the upper surface 90U of the fin 90 and the bottom of the opening 110 may cause difficulty for the deposition of the subsequently formed bottom isolation layer 107. A poorly formed bottom isolation layer 107 may be ineffective for reducing the leakage current of the NSFET device. The un-doped epitaxial material 106 fills the bottom portions of the openings 110 to reduce the vertical offset V, thereby making it easier to form the bottom isolation layer 107.

Next, the bottom isolation layer 107 is formed in the openings 110 on the un-doped epitaxial material 106. The bottom isolation layer 107 lines the bottoms of the openings 110. The bottom isolation layer 107 may be any suitable dielectric material (e.g., silicon oxide, silicon nitride, a low-K dielectric material, or the like) and is used for reducing or preventing leakage current. A suitable deposition method, such as CVD, ALD, PECVD, or the like, may be used to form the bottom isolation layer 107.

Next, source/drain regions 112 (e.g., 112A and 112B) are formed in the openings 110 on the bottom isolation layer 107. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial material of the source/drain regions 112 initially grows from the exposed surfaces of the second semiconductor material 54 to form epitaxial material 112A. As the epitaxial growth process continues, more epitaxial material, annotated as epitaxial material 112B in FIG. 11A, is grown on the epitaxial material 112A and fills the opening 110. The epitaxial material 112A and the epitaxial material 112B are collectively referred to as epitaxial source/drain regions 112 herein.

In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed, as illustrated in FIG. 11C. In other embodiments, these facets cause adjacent epitaxial source/drain regions 112 to merge. The upper surfaces of the epitaxial source/drain regions 112 may be flat, as illustrated in FIGS. 11A and 11C. In some embodiments, the upper surfaces of the epitaxial source/drain regions 112 may be curved, as illustrated by the dashed lines 112U in FIG. 11A.

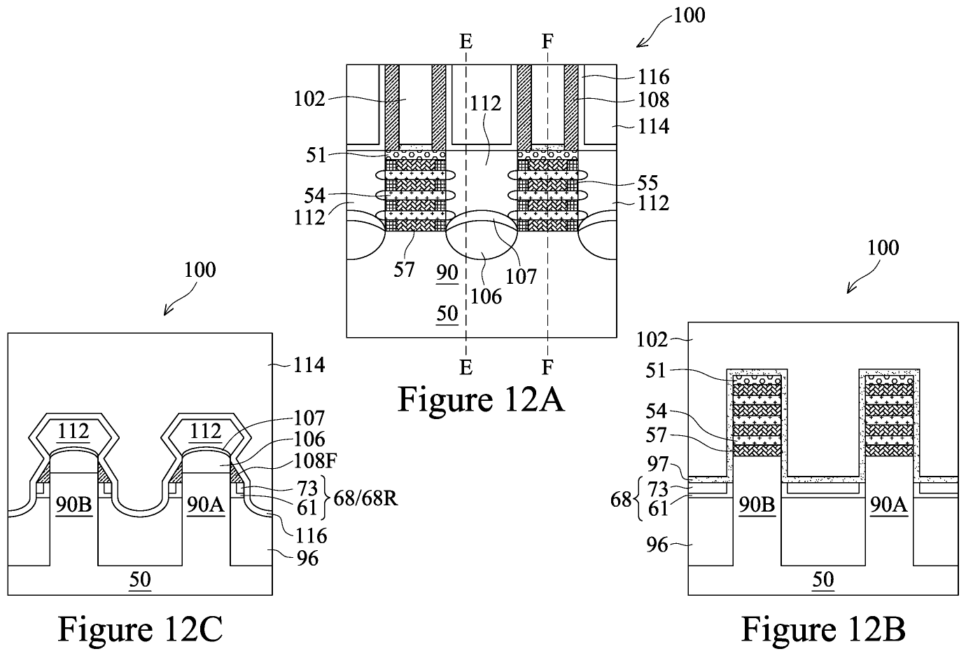

Next, in FIGS. 12A-12C, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

Next, a planarization process, such as CMP, is performed to remove the mask 104 and to expose the dummy gates 102. After the planarization process, the CESL 116, the first ILD 114, and the dummy gates 102 have a coplanar upper surface distal from the substrate 50.

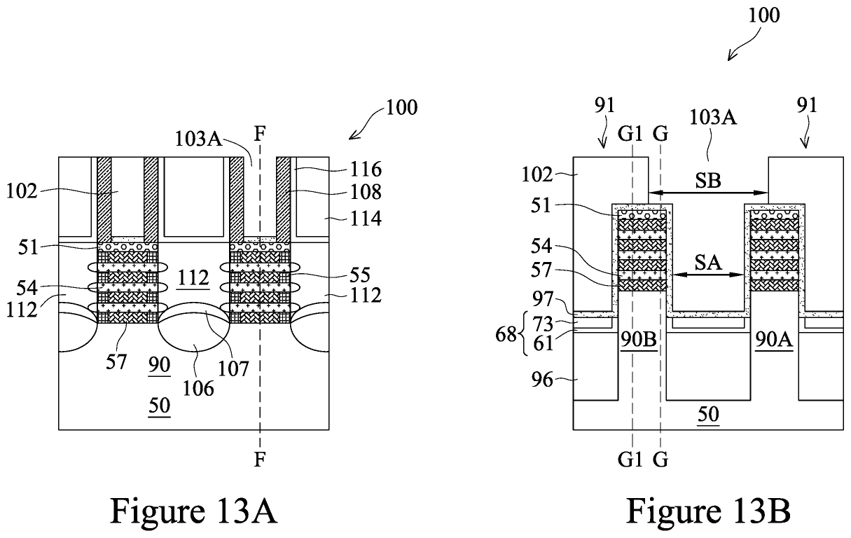

FIGS. 13A, 13B, 14A, 14B, 15A, 15B, 16A, 16B, 17A, 17B, 18A, 18B, 19A-19C, and 20A-20C illustrate a replacement gate process performed subsequently, where the dummy gate structures 101 are removed and replaced by replacement gate structures 123 (e.g., metal gate structures). A dielectric wall 133 is also formed to separate a replacement gate structure into two separate gate structures, and/or to reduce the gate-source capacitance C_{gd} of the NSFET device formed. The cross-sectional views corresponding to FIG. 12C are not illustrated for the replacement gate process, because such cross-sectional views are the same as FIG. 12C, in some embodiments.

Next, in FIGS. 13A and 13B, a portion of a dummy gate 102 disposed between two adjacent fin structures 91 is removed. An anisotropic etching process using an etchant selective to the material of the dummy gate 102 may be performed to remove the portion of the dummy gate 102. A patterned etching mask may be used by the anisotropic etching process. The opening in the patterned etching mask may have a width SB larger than a distance SA between the adjacent fin structures 91, such that besides the portion of the dummy gate 102 disposed between the adjacent fin structures 91, an upper portion of the dummy gate 102 disposed over the uppers surfaces of the fin structures 91 are also removed to form an opening 103A. In other words, the upper portion of the opening 103A is wider than a lower portion of the opening 103A. The opening 103A exposes the dummy gate dielectric 97.

FIG. 13B illustrates the cross-sectional view along cross-section F-F in FIG. 13A, and FIG. 13A illustrates the cross-sectional view along cross-section G-G in FIG. 13B. Note that the cross-section G-G is within the opening 103A in FIG. 13B, and therefore, the opening 103A is visible in the cross-section of FIG. 13A. FIG. 13B further illustrates a cross-section G1-G1 that extends through the remaining portion of the dummy gate 102. A cross-sectional view similar to FIG. 13A but along the cross-section G1-G1 would not show the opening 103A in FIG. 13A.

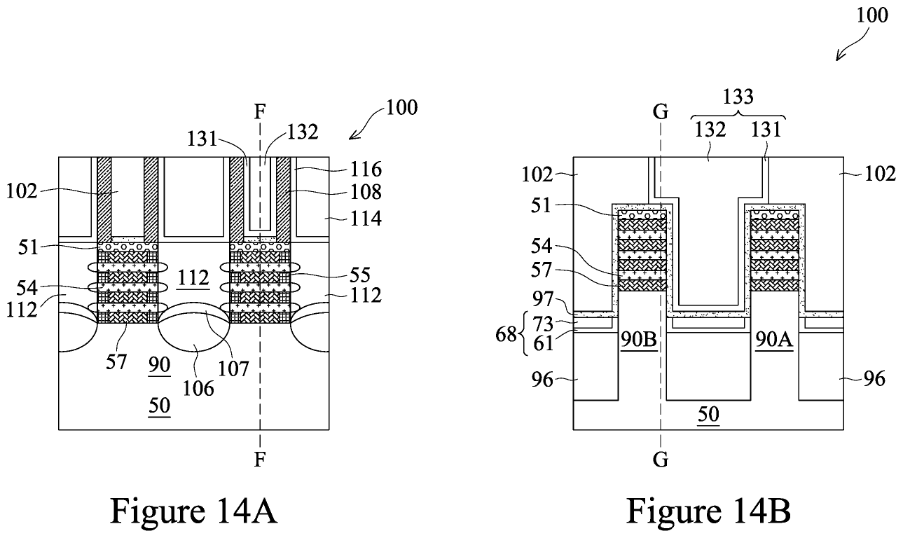

Next, in FIGS. 14A and 14B, a dielectric wall 133 (also referred to as a dielectric structure) is formed in the opening 103A. In some embodiments, the dielectric wall 133 is formed by lining sidewalls and the bottom of the opening 103A with a dielectric material 131, then filling the opening 103A with a dielectric material 132. The dielectric material 131 and the dielectric material 132 are formed of different materials to provide etching selectivity, in some embodiments. Suitable materials for the dielectric material 131 and the dielectric material 132 includes, e.g., silicon oxide, silicon nitride, silicon carbonitride, silicon oxycarbonitride, a low-K dielectric material (e.g., carbon-doped oxide), or the like, and may be formed using a suitable formation method, such as CVD, ALD, PECVD, FCVD, the like, or combinations thereof. For example, two different materials may be chosen from the above list of materials to form the dielectric material 131 and the dielectric material 132, respectively. In some embodiments, the dielectric wall 133 is formed of a single layer of dielectric material (e.g., 132). In some embodiments, the dielectric wall 133 is formed of more than two layers of dielectric materials. A planarization process, such as CMP, may be performed next to achieve a planar upper surface between the dummy gate 102 and the dielectric wall 133.

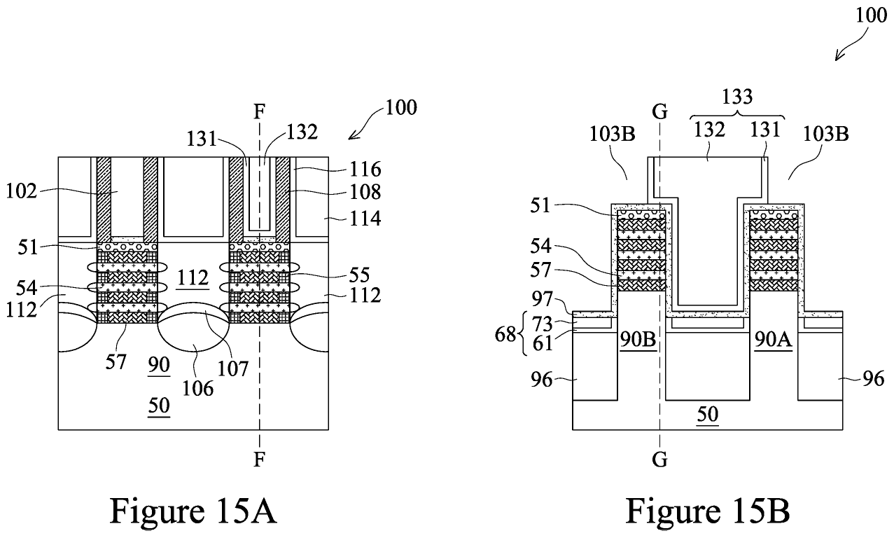

Next, in FIGS. 15A and 15B, the remaining portion of the dummy gate 102 (e.g., the portion not removed in the processing of FIGS. 13A and 13B to form the opening 103A) is removed to form an opening 103B between the gate spacers 108. Note that since FIG. 15A shows the cross-sectional view along cross-section G-G in FIG. 15B, the openings 103B is not visible in the cross-section of FIG. 15A. In some embodiments, the remaining portion of the dummy gate 102 is removed by an anisotropic dry etching process. For example, the etching process may include a dry etching process using reaction gas(es) that selectively etches the dummy gate 102 without etching the first ILD 114 and the gate spacers 108.

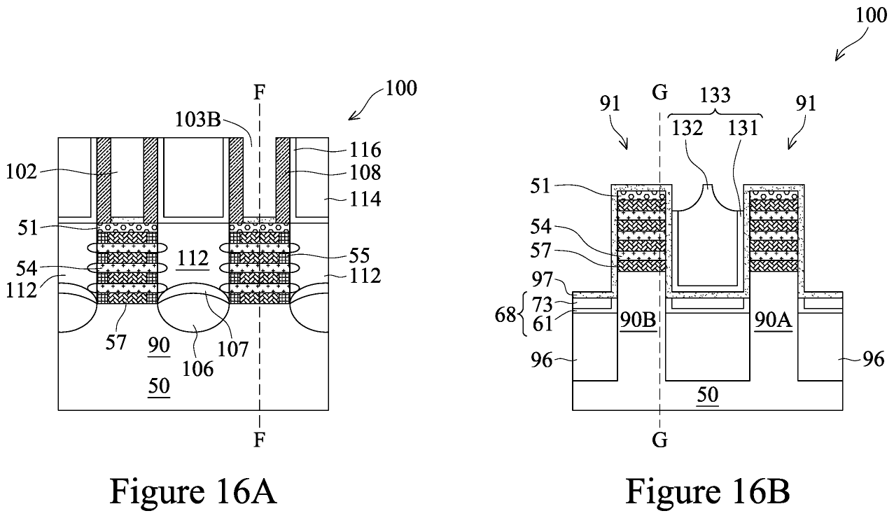

Next, in FIGS. 16A and 16B, a trimming process is performed to reshape the dielectric wall 133. In some embodiments, the trimming process comprises an anisotropic etching process, an isotropic etching process, or a combination of an anisotropic etching process and an isotropic etching process. The trimming process may additionally include a subsequent etching process, such as a chemical etch, a wet etch, or the like. The trimming process may use an etchant(s) that selectively etches the dielectric wall 133. In the illustrated embodiment, the trimming process removes the dielectric wall 133 from the upper surfaces of the fin structures 91, and reduces the width of an upper portion of (the remaining portion of) the dielectric wall 133. The lower portion of the dielectric wall 133 is not reached by the trimming process, thus the width of the lower portion of the dielectric wall 133 remains unchanged before and after the trimming process.

In the example of FIG. 16B, after the trimming process, the dielectric wall 133 is disposed between adjacent fin structures 91, and the upper portion of the dielectric wall 133 forms a protrusion. A width of the protrusion decreases as the protrusion extends away from the substrate 50. Portions of the dummy gate dielectric 97 between the fin structures 91 are covered by the dielectric wall 133, while other portions of the dummy gate dielectric 97 are exposed by the dielectric wall 133. In some embodiments, the trimming process is omitted. Examples of NSFET devices (e.g., 100E, 100F) formed without the trimming process are discussed hereinafter.

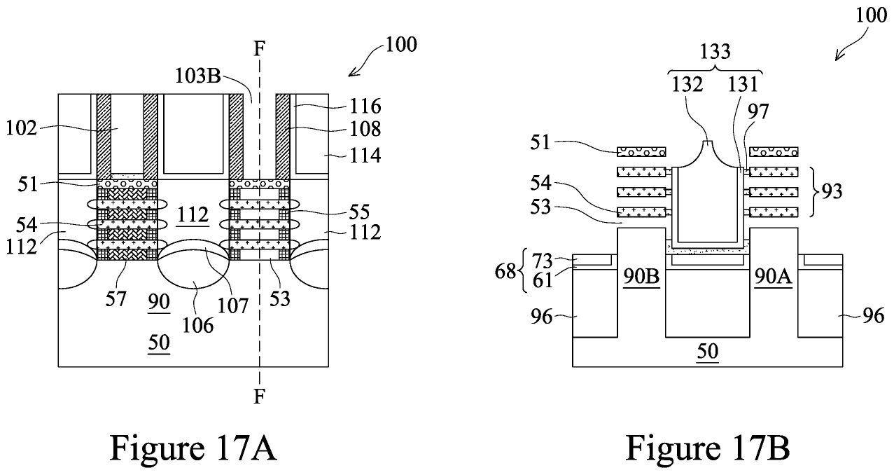

Next, in FIGS. 17A and 17B, the disposable material 57 and the dummy gate dielectric 97 are removed to release the second semiconductor material 54, which may be referred to as a sheet formation process. As illustrated in FIGS. 17A and 17B, after the disposable material 57 and the dummy gate dielectric 97 are removed, the second semiconductor material 54 (e.g., portions underlying the dummy gate 102 before the dummy gate 102 is removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100. The nanostructures 54 vertically stacked over a fin 90 may be collectively referred to as channel stacks or stacked nanostructures. As illustrated in FIGS. 17A and 17B, due to the removal of the disposable material 57, gaps 53 (e.g., empty spaces) are formed between the nanostructures 54, between the dummy sheets 51 and the uppermost nanostructures 54, and between the lowermost nanostructures 54 and the fins 90. In some embodiments, the nanostructures 54 are nanosheets or nanowires, depending on, e.g., the dimensions (e.g., size and/or aspect ratio) of the nanostructures 54.

In some embodiments, the sheet formation process is a selective etching process performed using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride, diluted hydrogen fluoride, another fluorine-based etchant, or the like, may be used to remove the disposable material 57. In the illustrated embodiment, the selective etching of the sheet formation process also removes the dummy gate dielectric 97 disposed along upper surfaces of the nanostructures 54, lower surfaces of the nanostructures 54, and sidewalls of the nanostructures 54 facing away from the respective dielectric wall 133. Notably, in the example of FIG. 17B, while the selective etching of the sheet formation process removes most of the dummy gate dielectric 97 disposed along sidewalls of the nanostructures 54 facing the respective dielectric wall 133, some portions of the dummy gate dielectric 97 along those sidewalls (e.g., portions disposed between the nanostructures 54 and the dielectric wall 133) remain. In addition, the portion of the dummy gate dielectric 97 disposed under the dielectric wall 133 also remains, in some embodiments. In the example of FIG. 17B, the dielectric material 131 of the dielectric wall 133 is exposed after the sheet formation process.

In some embodiments, a high etching selectivity of 10,000 or more is achieved between the disposable material 57 and the second semiconductor material 54. In other words, the disposable material 57 is removed by the isotropic etching process at an etching rate 10,000 times or more than the etching rate of the second semiconductor material 54. As a result, the etching process (e.g., the sheet formation process) used to remove the disposable material 57 causes little or no damage to the nanostructures 54.

In some embodiments, both the disposable material 57 and the STI regions 96 are formed of an oxide (e.g., silicon oxide). Without the STI protection structure 68, the sheet formation process may remove upper portions of the STI regions 96 exposed by the openings 103B (e.g. portions directly under the dummy gate 102), thus causing recessing of the STI regions 96. The recessing of the STI regions 96 reduces the distance between the subsequent formed replacement gate structure and the substrate 50. In addition, corner regions of the STI regions 96 (e.g., regions where the upper surfaces of the STI regions 96 contact the sidewalls of the fins 90) may be removed (e.g., etched away) at a faster rate than other regions of the STI regions 96 during the sheet formation process. When the subsequently formed replacement gate structure fills the removed corner regions of the STI regions 96, protrusion of the replacement gate structure occurs. The reduced distance between the replacement gate structure and the substrate, as well as the protrusion of the replacement gate structure, cause an increase in the parasitic capacitance of the replacement gate structure. The present disclosure, by forming the STI protection structure 68, prevents or reduces the likelihood of STI region loss during the sheet formation process, thus reducing the parasitic capacitance of the NSFET device formed and improving the device performance.

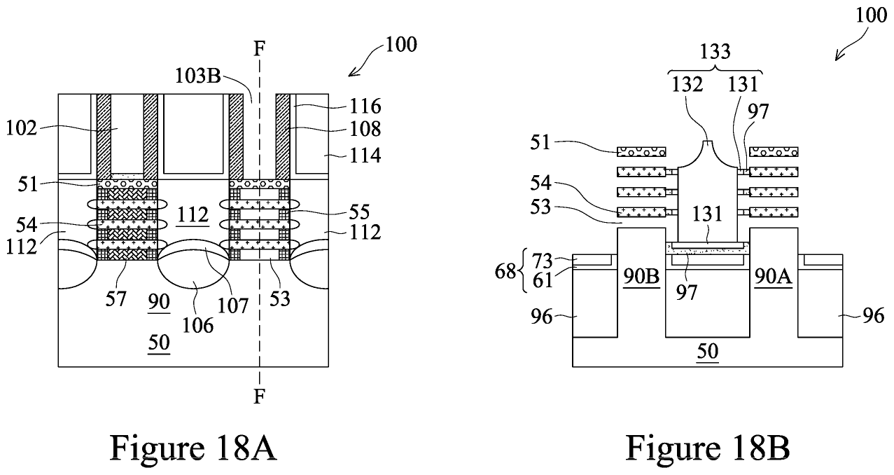

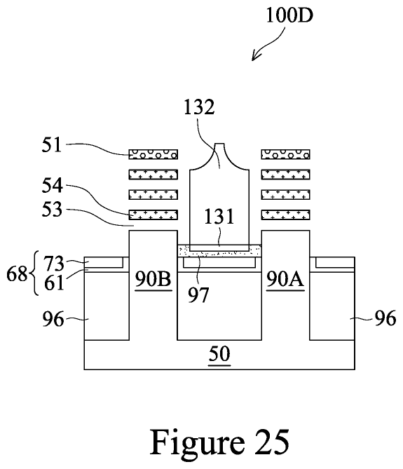

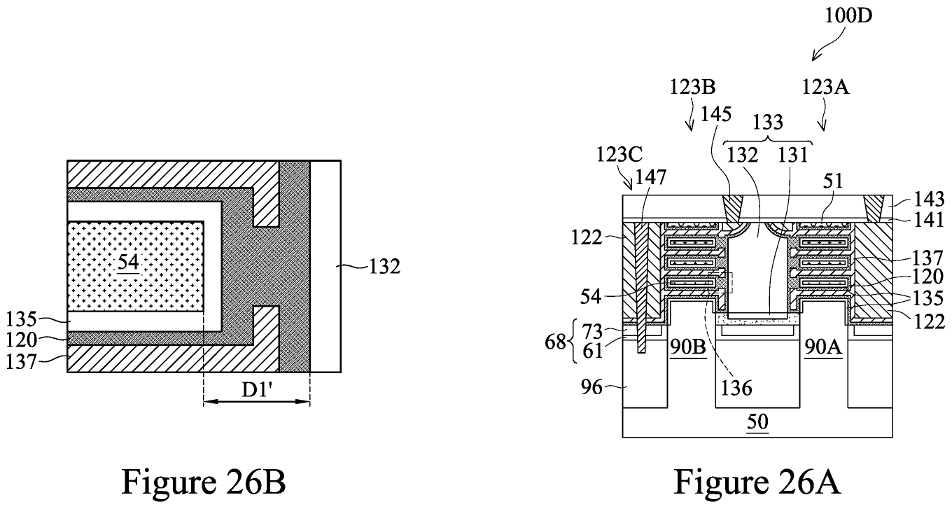

Next, in FIGS. 18A and 18B, an additional selective etching process is performed to adjust the spacing (e.g., the empty space) between the nanostructures 54 and the dielectric wall 133. In some embodiments, the additional selective etching process is performed using an etchant(s) that selective etches the dielectric material 131. In the example of FIG. 18B, after the additional selective etching process, while most of the dielectric material 131 is removed, some portions of the dielectric material 131 still remain between (the remaining portions of) the dummy gate dielectric 97 and the dielectric wall 133, which causes the so-called π-gate to be formed, details of which are discussed hereinafter. In some embodiments, the additional selective etching process removes (e.g., completely removes) the dielectric material 131 and the remaining portions of the dummy gate dielectric 97. An example is discussed hereinafter with reference to FIGS. 25, 26A, and 26B. In some embodiments, depending on the material selections (e.g., for the dummy gate dielectric 97 and the dielectric material 131) and the etchant used for the sheet formation process, the selective etching of the sheet formation process of FIGS. 17A and 17B already achieves the same effect to the dummy gate dielectric 97 and the dielectric material 131 as shown in FIGS. 18A and 18B, and therefore, the additional selective etching process of FIGS. 18A and 18B is omitted.

Next, in FIGS. 19A-19C, an opening 103C is formed by removing a second dummy gate structure adjacent to the first dummy gate structure removed for forming the opening 103B, then removing the disposable material 57 under the second dummy gate structure. FIGS. 19B and 19C illustrate the cross-sectional views along cross-sections F-F and H-H in FIG. 19A, respectively.

In some embodiments, to form the opening 103C, a patterned mask layer, such as a patterned photoresist layer, is formed over the first ILD 114 and fills the opening 103B. The opening in the patterned mask layer exposes the second dummy gate structure at the location of the opening 103C. Next, one or more etching processes are performed to remove the second dummy gate structure exposed by (e.g., directly under) the opening in the patterned mask layer. Next, the sheet formation process (e.g., a selectively etching process) is performed to selectively remove the disposable material 57. After the sheet formation process, the remaining portions of the second semiconductor material 54 under the second dummy gate structure form nanostructures 54. Details are the same as or similar to those discussed above, thus not repeated. The patterned mask layer (e.g., a patterned photoresist layer) is then removed by a suitable removal process such as ashing.

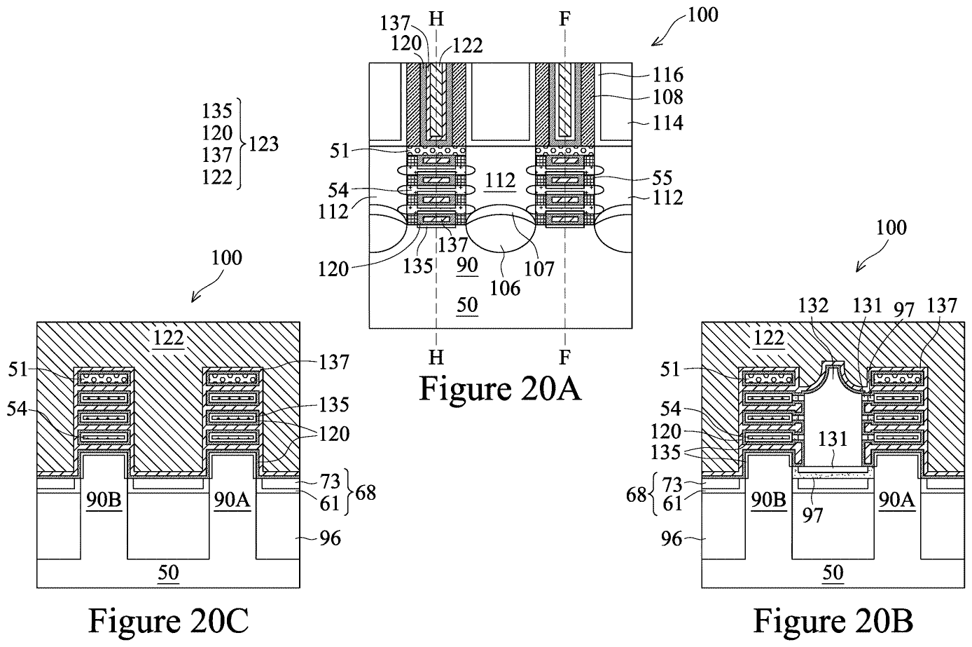

Next, in FIGS. 20A-20C, replacement gate structures 123 are formed around the nanostructures 54. Each of the replacement gate structures 123 includes a gate dielectric layer 120, a work function material 137, and a gate electrode 122. Each replacement gate structure 123 may additionally include an interfacial layer (IL) 135. FIGS. 20B and 20C illustrate the cross-sectional views along cross-sections F-F and H-H in FIG. 20A, respectively.

The IL 135 may include a dielectric material such as silicon oxide or silicon oxynitride. The IL 135 may be formed by chemical oxidation, thermal oxidation, atomic layer deposition (ALD), chemical vapor deposition (CVD), and/or other suitable formation processes. In an embodiment, the IL 135 is formed by converting an exterior portion of the nanostructures 54 into an oxide (e.g., silicon oxide) using, e.g., an oxidization process. The IL 135 may also be formed along the exposed surfaces of the fins 90 by the oxidization process. Note that in the illustrated embodiment, no IL 135 is formed on the surfaces of the dummy sheets 51.

Next, a gate dielectric material 120 is deposited conformally in the openings 103 (e.g., 103B and 103C), such as along the top surfaces and the sidewalls of the fins 90, and along sidewalls of the gate spacers 108. The gate dielectric material 120 may also be formed on the top surface of the first ILD 114. Notably, the gate dielectric material 120 is formed to wrap around the nanostructures 54 and the dummy sheets 51. In accordance with some embodiments, the gate dielectric material 120 comprises silicon oxide, silicon nitride, or multilayers thereof. In some embodiments, the gate dielectric material 120 comprises a high-K dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a work function material 137 is deposited over and around the gate dielectric material 120. In the illustrated embodiments, the work function material 137 is illustrated as a single layer of material for simplicity, with the understanding that the work function material 137 may include multiple layers of different work function materials, as readily appreciated by skilled artisans.

Examples of p-type work function materials that may be included in the replacement gate structures 123 include TiN, TaN, Ru, Mo, Al, WN, ZrSi₂, MoSi₂, TaSi₂, NiSi₂, other suitable p-type work function materials, or combinations thereof. Examples of n-type work function metals that may be included in the replacement gate structures 123 include Ti, Ag, TaAl, TaAlC, TiAlN, TaC, TaCN, TaSiN, Mn, Zr, other suitable n-type work function materials, or combinations thereof. A work function value is associated with the material composition of the work function material, and thus, the work function material(s) is chosen to tune its work function value so that a target threshold voltage Vt is achieved in the device formed. The work function material(s) may be deposited by CVD, physical vapor deposition (PVD), ALD, or other suitable process.

In the illustrated embodiments, the work function material 137 extends along the gate dielectric material 120, and wraps around the nanostructures 54 and the dummy sheets 51. Notably, the work function material 137 fills the spaces between vertically adjacent nanostructures 54, between the dummy sheets 51 and the uppermost nanostructures 54, and between the fins 90 and the lowermost nanostructures 54. In addition, the work function material 137 fills the spaces between the nanostructures 54 and dielectric wall 133, and extends along exposed portions of the exterior surfaces of the dielectric wall 133.

Next, a gate electrode material 122 is deposited over and around the work function material 137, and fills the remaining portions of the opening 103. The gate electrode material may include a metal-containing material such as TiN, TiO, TaN, TaC, Co, Ru, Al, W, combinations thereof, or multi-layers thereof.

Referring next to FIGS. 21A-21F, FIGS. 21B, 21C, and 21E illustrate cross-sectional views along cross-sections F-F, H-H, and E-E of the NSFET device 100 in FIG. 21A, respectively. FIG. 21D illustrates a zoomed-in view of an area 134 in FIG. 21B. FIG. 21F illustrates an example top view of the NSFET device 100.

As illustrated in FIGS. 21A-21F, the dielectric wall 133, the gate dielectric material 120, the work function material 137, and the gate electrode material 122 are recessed by a controlled removal process, such as a planarization process (e.g., CMP), an etch back process, combinations thereof, or the like. In some embodiments, the controlled removal process continues until the dielectric layers 51 are exposed. In other words, the controlled removal process stops at a vertical level (e.g., a horizontal plane) between the upper surface and the lower surface of the dielectric layers 51 in FIGS. 19A-19C. Depending on the heights of the dielectric layers 51 and the source/drain regions 112, the controlled removal process may remove (e.g., completely remove) the gate spacers 108, the CESL 116, and the first ILD 114. The controlled removal process may also thin (e.g., remove upper portions of) the dielectric layers 51. A thickness of the (thinned) dielectric layers 51 may be between about 1 nm and about 8 nm. The dielectric layer 51 may be used as a control point (e.g., a stopping point) to stop the controlled removal process. After the controlled removal process is completed, the remaining portions of the gate dielectric material 120, the work function material 137, and the gate electrode material 122, together with the IL 135, form the replacement gate structures 123 (e.g., 123A, 123B, and 123C) in the final product. The replacement gate structures 123 may also be referred to as gate structures, gate stacks, or metal gate structures. In the example of FIGS. 21A-21F, after the controlled removal process is completed, the dielectric wall 133, the dielectric layers 51, the gate dielectric material 120, the work function material 137, the gate electrode material 122, and the source/drain regions 112 have a coplanar upper surface.

In the example of FIG. 21B, the upper surface of the upper portion (e.g., the protrusion) of dielectric wall 133 is level with the upper surface of the dielectric layers 51. Therefore, the dielectric wall 133 separates (e.g., cuts) the replacement gate structure into a replacement gate structure 123A around the nanostructures 54 overlying the fin 90A, and a replacement gate structure 123B around the nanostructures 54 overlying the fin 90B. A width W of the lower portion of the dielectric wall 133 (e.g., disposed between the fins 90 or the nanostructures 54) is between about 15 nm and about 50 nm, and a width W_{T} of the upper portion (e.g., the protrusion) of the dielectric wall 133 (e.g., disposed between the dummy sheets 51) is between about 10 nm and about 20 nm, in some embodiments. A height H_{T} of the protrusion of the dielectric wall 133 may be between about 0 nm and about 20 nm, as an example. A distance H_{O} between the upper surface of the dielectric wall 133 and the upper surface of the uppermost nanostructure 54 is between about 0 nm and about 10 nm, in some embodiments.

FIGS. 21B, 21E, and 21F further illustrate a gate isolation structure 147 that extends through the gate electrode material 122, through the STI protection structure 68, through the first ILD 114, through the CESL 116, and into the STI regions 96. FIG. 21F shows a top view of the gate isolation structure 147. In FIG. 21B, the gate isolation structure 147 separates portions (e.g. left portion in FIG. 21B) of the gate electrode material 122 from the replacement gate structure 123B, and the left portion of the gate electrode material 122 may form another replacement gate structure 123C around nanostructures 54 (not shown in FIG. 21B) formed to the left of the fin 90B.

In some embodiments, the gate isolation structure 147 is formed by a Cut Metal Gate (CMG) process. For example, after the controlled removal process, a patterned mask layer (e.g., a patterned photoresist layer) is formed over the gate electrode material 122 and the first ILD 114. The opening in the patterned mask layer exposes portions of the gate electrode material 122 and portions of the first ILD 114 that underly the opening. An anisotropic etching process is then performed to remove exposed portions of the gate electrode material 122 and the first ILD 114 to form a trench. The trench is formed to extend through the first ILD 114 and the CESL 116 (see FIG. 21E) and into the STI regions 96. Next, the trench is filled with a dielectric material, such as silicon oxide, silicon nitride, silicon carbonitride, silicon oxycarbonitride, a low-K dielectric material, multi-layers thereof, or the like, to form the gate isolation structure 147. In some embodiments, the gate isolation structure 147 is formed of a same material as the dielectric wall 133 (e.g., the dielectric material 132). A width of the gate isolation structure 147 may be between about 10 nm and about 20 nm, as an example.

Skilled artisans will readily appreciate that besides the CMG process, the gate isolation structure 147 may alternatively be formed by a Cut Poly Gate (CPG) process. In the CPG process, the dummy gate structure is cut by the gate isolation structure 147 before the replacement gate process is performed. The gate isolation structure 147 may be formed by, e.g., etching using a patterned mask layer to form an opening at the location of the gate isolation structure 147, and filling the opening with suitable dielectric material(s). After the gate isolation structure 147 is formed, the dummy gate structure is replaced by the replacement gate structure in subsequent processing. These and other variations are fully intended to be included within the scope of the present disclosure.

As illustrated in FIG. 21F, the gate isolation structure 147 extends parallel to the fins 90, and extends beyond opposing sidewalls of the replacement gate structure 123 cut by the gate isolation structure 147. Furthermore, as illustrated in FIG. 21E, the gate isolation structure 147 extends between, and is spaced apart from, neighboring source/drain regions 112. The number and the location of the gate isolation structure 147 illustrated in FIG. 21F is illustrative and non-limiting.

Still referring to FIGS. 21A-21F, next, an etch stop layer (ESL) 141 is formed over the gate structures 123, the source/drain regions 112, and the first ILD 114. In an embodiment, ESL 141 is formed of silicon nitride using, e.g., PECVD, although other dielectric materials such as nitride, carbide, boride, combinations thereof, or the like, and alternative techniques of forming the ESL 141, such as CVD, low-pressure CVD (LPCVD), PVD, ALD, or the like, could alternatively be used.

Next, a dielectric layer 143 is formed over the ESL 141. The dielectric layer 143 may be formed of a suitable material such as silicon oxide, a low-K dielectric material, or the like, by a suitable formation method such as CVD, PECVD, FCVD, or the like. Next, gate contacts 145 (e.g., vias) are formed to extend through the dielectric layers 143 and the ESL 141 and electrically couple to the replacement gate structures 123. Source/drain contracts 149 (e.g., vias) are formed to extend through the dielectric layers 143 and the ESL 141 and electrically couple to the source/drain regions 112.

Note that in the example of FIG. 21B, since the upper portion (e.g., the protrusion) of the dielectric wall 133 is narrower than the lower portion of the dielectric wall 133, the gate electrode material 122 is formed between the dummy sheets 51 and the upper portion of the dielectric wall 133. In contrast, no gate electrode material 122 is formed between the nanostructures 54 and the lower portion of the dielectric wall 133. The narrower upper portion of the dielectric wall 133 allows gate contacts 145 to be formed laterally between the dummy sheets 51 and the dielectric wall 133, as illustrated by the gate contract labeled as 145A in FIG. 21B. In other words, the narrower upper portion of the dielectric wall 133 allows for greater flexibility for the location of the gate contacts 145. Without the narrower upper portion of the dielectric wall 133, the gate contact 145 may have to formed at an opposite side of the dielectric wall 133 from the nanostructures 54, as illustrated by the gate contact labeled as 145B in FIG. 21B.

FIG. 21D shows a zoomed-in view of an area 134 in FIG. 21B. As illustrated in FIG. 21D, a remaining portion of the dummy gate dielectric 97 and a remaining portion of the dielectric material 131 are disposed between the nanostructure 54 and the dielectric material 132 of the dielectric wall 133. As a result, the gate dielectric material 120 extends along exterior surfaces of the nanostructure 54, the remaining portion of the dummy gate dielectric 97, the remaining portion of the dielectric material 131, and the dielectric material 132. The shape of the gate dielectric material 120 in the cross-section of FIG. 21D resembles the shape of Greek letter π, and therefore, the corresponding replacement gate structure 123 is also referred to as a π-gate 123. In the example of FIG. 21D, a distance D₁ between the right sidewall of the nanostructure 54 and the sidewall of the dielectric material 132 is between about 0 nm and about 5 nm. A distance D₂ between the lower surface (or the upper surface) of the nanostructure 54 and the upper surface (or the lower surface) of a respective portion of the gate dielectric material 120 adjacent to the nanostructure 54 is between about 0 nm and about 2 nm. Note that the π-gate 123 does not wrap completely around the nanostructures 54. In particular, the right sidewall of the nanostructure 54 in FIG. 21D is not completely covered by the π-gate 123. The distance D₂ therefore measures the partial coverage of (e.g., how much the π-gate 123 covers) the sidewall of the nanostructure 54 not completely covered by the π-gate 123.

FIG. 21F illustrates an example top view of the NSFET device 100. Note that for simplicity, not all features are illustrated. For example, FIG. 21F only illustrates the fins 90, the replacement gate structures 123, the dielectric walls 133, and a gate isolation structure 147. Note that the number of fins, replacements gate structures, dielectric walls, and gate isolation structures, as well as the locations of the above structures in FIG. 21F are illustrative and non-limiting. FIG. 21B corresponds to the cross-sectional view along cross-section I-I in FIG. 21F.

In FIG. 21F, a plurality of dielectric walls 133 are embedded in respective, different replacement gate structures 123 along a same row. The plurality of dielectric walls 133 along the same row may be formed at the same time using the same processing steps. For example, the dashed rectangle 133M shows the opening in a patterned mask layer that is used to form the openings 103 in respective dummy gates 102. The dielectric walls 133 within the dashed rectangle 133M have a same width W.

FIG. 21F further illustrates dielectric walls 133 formed within a dashed rectangle 133MA and a dashed rectangle 133MB. Similar to the dashed rectangle 133M, the dashed rectangle 133MA and the dashed rectangle 133MB represent the opening of a patterned mask layer that is used to form the dielectric walls 133. The dielectric walls 133 within the dashed rectangle 133MA and the dashed rectangle 133MB have different widths. For example, the dielectric walls 133A within the dashed rectangle 133MA have a same width W₁, and the dielectric walls 133B within the dashed rectangle 133MB have a same width W₂, where W₂>W₁. The difference between the widths (e.g., W₂, W₁) of the dielectric walls 133 may be between about 0 nm and about 15 nm. The gate isolation structure 147 has a width W₃. In some embodiments, the width W₃ is smaller than the width of the dielectric wall 133 (e.g., W₃<W, or W₃<W₁, or W₃<W₂), such that the gate isolation structure 147 may be formed inside (e.g., embedded in) a dielectric wall 133 (see, e.g., 22B).

FIG. 21F illustrates the distance D₃ between adjacent fins 90, which may be between about 20 nm and about 55 nm. Note that in the top view of FIG. 21F, opposing sidewalls of each fin 90 may overlap (e.g., completely overlap) the corresponding sidewalls of the nanostructures 54 overlying the fin 90. The distance S between the fin 90 and an adjacent dielectric wall 133 may be between 0 nm and about 10 nm. In particular, the distance S may be 0 nm, which means the fin 90 (or the nanostructures 54) is in physical contact with the dielectric wall 133.

Various advantages are achieved by the disclosed embodiments. For example, the dielectric wall 133 reduces the size of the gate electrode 122, which in turn reduces the gate-source capacitance Cgd (which is a parasitic capacitance) between the gate electrode 122 and the source/drain regions 112. The dielectric layer 51 (e.g., the dummy sheet) in the fin structure 91 also helps to reduce the gate-source capacitance Cgd, because the dielectric layer 51 servers as a stopping point for the controlled removal process discussed above, which controlled removal process removes portions of the gate electrode 122 disposed above the dielectric layer 51, thus reducing the size of the gate electrode 122. Without the dielectric layer 51, the controlled removal process may not be possible, or may have to stop well above the dielectric layer 51 to avoid damaging the uppermost nanostructures 54. Due to the reduced gate-source capacitance Cgd of the disclosed embodiments, the RC delay of the NSFET device formed is reduced, and the power consumption of the NSFET device is also reduced. Simulations have shown that compared with an NSFET device without the disclosed features, the gate-source capacitance Cgd of the disclosed embodiments may be reduced by 10% to 15%, and the power efficiency of the disclosed embodiments may be improved by 10% to 20%.

In addition, the dielectric wall 133 allows further scaling down of the distance D₃ between adjacent fins/channel stacks/stacked nanostructures, thus reducing cell height and improving integration density of the NSFET device 100. Compared with a reference NSFET device using only gate isolation structures 147 to separate (e.g., cut) replacement gate structures 123, the disclosed embodiments herein achieve 25% to 35% reduction in the distance D₃ between adjacent fins 90. The reduction in the distance D₃ is achieved at least in part by the self-aligned manner of formation of the dielectric wall 133. Recall that in FIGS. 14A and 14B, the dielectric wall 133 is formed by filling the opening 103A with dielectric material(s). The self-aligned manner of formation ensures a consistent structure for the replacement gate structure 123, which consistent structure is not constrained by photolithography critical dimension (CD) or overlay constraints. For example, the π-gate (see FIG. 21D) can always be formed consistently, such that a portion of the nanostructure 54 is not covered by the gate dielectric material 120 and the work function material 137. In contrast, in the reference NSFET device (which uses only gate isolation structure 147 to cut the replacement gate structure), the photolithography CD and overlay constraints may affect where the gate isolation structure 147 is formed, which in turn affects the structure of the replacement gate structure. For example, if the gate isolation structure 147 is formed too close to a sidewall of the nanostructures 54, the gate isolation structure 147 may accidentally remove the gate dielectric material 120 and the work function material 137 disposed along the sidewall of the nanostructure 54. For this reason, the reference NSFET device may have to leave safety margins (e.g., distances) on both sides of the gate isolation structure 147 to avoid accidentally changing the structure of the replacement gate structure 123, which prevents further reduction of the distance D₃ between adjacent fins 90.

Another advantage of having the dielectric layer 51 in the fin structure 91 is the uniform thickness of the work function material 137 around all nanostructures 54. In particular, due to the dielectric layer 51, the work function material 137 between the uppermost nanostructures 54 and the dielectric layers 51 have a same thickness as the work function material 137 between vertically adjacent nanostructures 54. The uniform thickness of the work function material 137 helps to achieve a uniform threshold voltage Vₜ for the NSFET device 100.

The disclosed gate structures (e.g., π-gate) achieve performance balance between reduction of distance D₃ and gate control. As discussed above, the dielectric wall 133 allows for further reduction of the distance D₃. However, the dielectric wall 133 may prevent the work function material 137 from being formed in the space between the nanostructures 54 and the dielectric wall 133. In other words, one sidewall of the nanostructure 54 may not be controlled by the replacement gate structure 123. The π-gate (see FIG. 21D), by partially covering the sidewall of the nanostructure 54 facing the dielectric wall 133 with the gate dielectric material 120 and the work function material 137, allows better control (e.g., turning ON/OFF) of the channel regions of the NSFET device 100 to counter the short channel effect (SCE) in devices formed by advanced semiconductor manufacturing processes.

Additional processing steps may be performed to complete the fabrication of the NSFET device 100, as skilled artisans readily appreciate. For example, an interconnect structure, which includes multiple dielectric layers and conductive features (e.g., vias and conductive lines) formed in the multiple dielectric layers, is formed to interconnect the underlying electrical components (e.g., NSFETs) to form functional circuits. Next, external connectors (e.g., copper pillars, conductive bumps) may be formed to be electrically coupled to the interconnect structure to provide electrical connection to external electrical devices. Dicing may be performed to separate multiple NSFET devices 100 formed on a wafer into separate (e.g., individual) devices. Details are not discussed here.

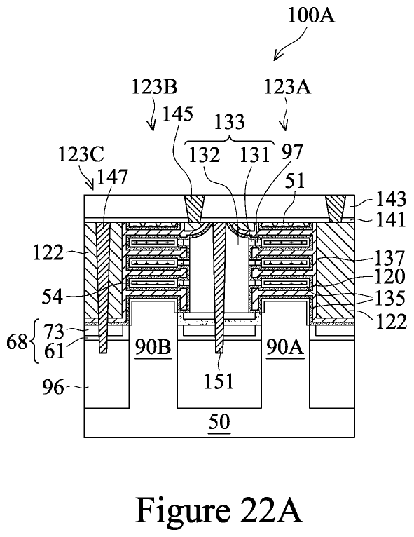

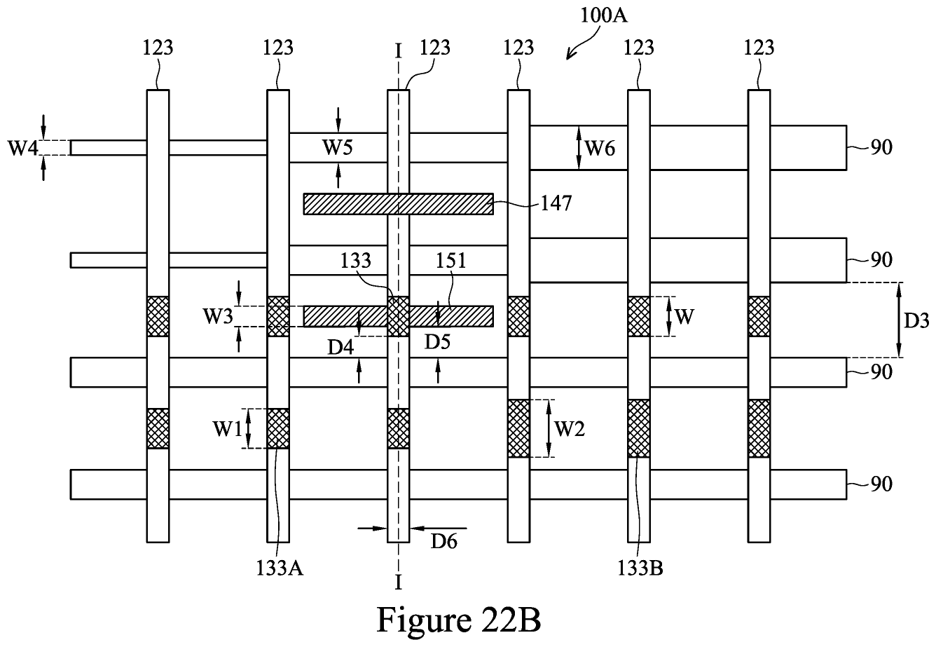

FIGS. 22A and 22B are various views (e.g., cross-sectional view, top view) of a portion of an NSFET device 100A, in accordance with another embodiment. The cross-sectional view of FIG. 22A corresponds to that of FIG. 21B, and FIG. 22B is an example top view of the NSFET device 100A. Other cross-sectional views of the NSFET device 100A are the same as or similar to those of NSFET device 100.

The NSFET device 100A is similar to the NSFET device 100, but with an additional gate isolation structure 151 that cuts through the dielectric wall 133, as illustrated in FIGS. 22A and 22B. In the example of FIGS. 22A and 22B, both the gate isolation structure 151 and the dielectric wall 133 are used to separate (e.g., cut) the replacement gate structure 123 into separate replacement gate structures. The gate isolation structure 151 further enhances the isolation between the two columns of nanostructure 54 over adjacent fins 90. The formation method and the dimension of the gate isolation structure 151 may be the same as or similar to the gate isolation structure 147, thus details are not repeated.

In the example of FIG. 22B, a distance D₆ between two opposing sidewalls (e.g., sidewalls extending parallel to cross-section I-I) of the dielectric wall 133 is the same as the distance between two respective opposing sidewalls of a respective replacement gate structures 123, such that the two opposing sidewalls of the dielectric wall 133 overlap (e.g., overlap completely) with the two respective opposing sidewalls of the respective replacement gate structure 123. In addition, a distance D₄ between an edge of the dielectric wall 133 and a respective fin 90 (e.g., a closest fin) is smaller than a distance D₅ between an edge of the isolation structure 151 and a respective fin 90 (e.g., a closest fin). In the illustrated embodiment of FIG. 22B, at least some of the fins 90 (e.g., the two fins at the top) have different widths at different segments of the fins 90. For example, the fin 90 at the top has a first width W₄ at a first segment, has a second width W₅ at a second segment, and has a third width W₆ at a third segment, where W₄<W₅<W₆.

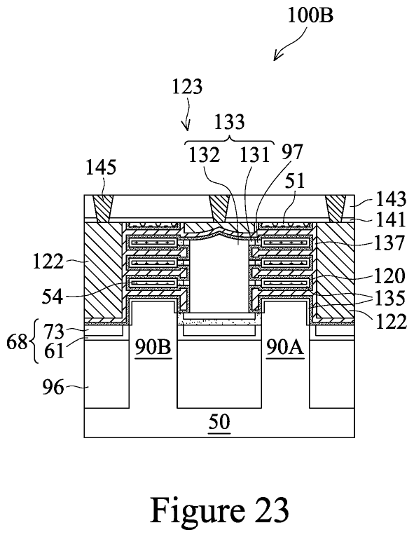

FIG. 23 is a cross-sectional view of a portion of an NSFET device 100B, in accordance with another embodiment. The cross-sectional view of FIG. 23 corresponds to that of FIG. 21B. Other cross-sectional views of the NSFET device 100B are the same as or similar to those of NSFET device 100.

The NSFET device 100B is similar to the NSFET device 100, but the dielectric wall 133 has a smaller height, such that the protrusion of the dielectric wall 133 is below (e.g., closer to the substrate) than the upper surface of the gate electrode material 122. As a result, the gate electrode 122 electrically couples the nanostructures 54 overlying both the fins 90A and 90B. In other words, the two NSFETs shown in FIG. 23 are electrically coupled together.

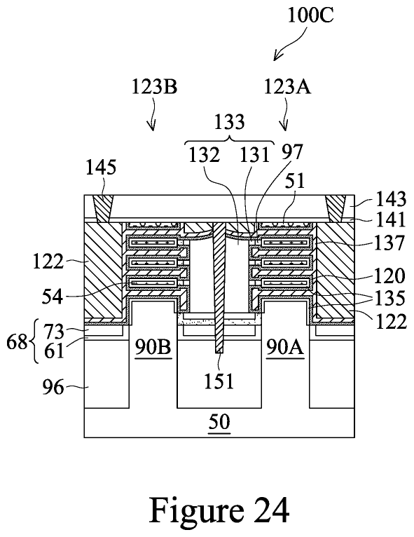

FIG. 24 is a cross-sectional view of a portion of an NSFET device 100C, in accordance with another embodiment. The NSFET device 100C is similar to the NSFET device 100B, but with a gate isolation structure 151 that separates (e.g., cuts) the replacement gate structure 123 into two separate replacement gate structures 123A and 123B. For example, the gate isolation structure 151 extends through the gate electrode material 122, through the dielectric wall 133, through the STI protection structure 68, and into the STI regions 96.

FIGS. 25, 26A, and 26B are cross-sectional views of a portion of an NSFET device 100D at various stages of manufacturing, in accordance with another embodiment. The cross-sectional view of FIG. 25 corresponds to that of FIG. 18B. In particular, FIG. 25 shows an alternative embodiment where the additional selective etching process of FIG. 18B removes (e.g., completely removes) the dielectric material 131 and the remaining portions of the dummy gate dielectric 97.

Next, following the same or similar processing steps in FIGS. 19A-19C, 20A-20C, and 21A-21F, the NSFET device 100D of FIG. 26A is formed. The cross-sectional view of FIG. 26A corresponds to that of FIG. 21B. Other cross-sectional views of the NSFET device 100D are the same as or similar to those of NSFET device 100.

FIG. 26B shows a zoomed-in view of an area 136 in FIG. 26A. As illustrated in FIG. 26B, the gate dielectric material 120 completely wraps around the nanostructure 54, and extends continuously from the nanostructure 54 to the dielectric material 132. A distance D′₁ between the sidewall of the nanostructure 54 facing the dielectric material 132 and the dielectric material 132 is between about 2 nm and about 5 nm. Note that in the dielectric wall 133, the remaining portion of the dielectric material 131 is disposed under the dielectric material 132, and no dielectric material 131 is disposed along the sidewalls of the dielectric material 132.

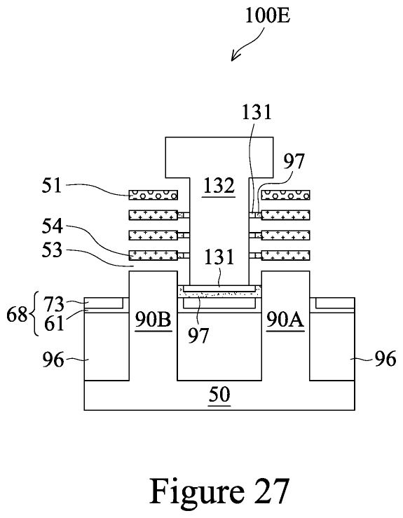

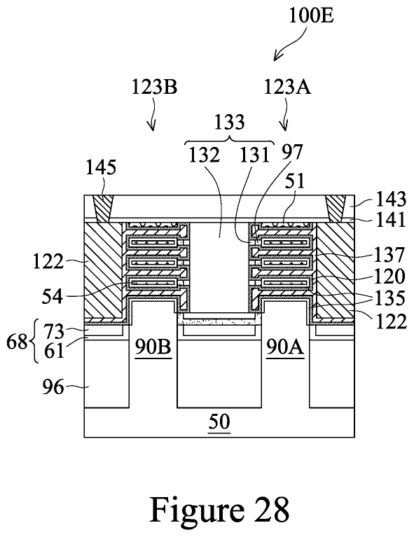

FIGS. 27 and 28 are cross-sectional views of a portion of an NSFET device 100E at various stages of manufacturing, in accordance with another embodiment. The NSFET device 100E is similar to the NSFET device 100, but without the trimming process for the dielectric wall 133. In particular, the cross-sectional view of FIG. 27 corresponds to that of FIG. 18B, but without the trimming of the dielectric wall 133.

Next, following the same or similar processing steps in FIGS. 19A-19C, 20A-20C, and 21A-21F, the NSFET device 100E of FIG. 28 is formed. The cross-sectional view of FIG. 28 corresponds to that of FIG. 21B. Other cross-sectional views of the NSFET device 100E are the same as or similar to those of NSFET device 100. In the example of FIG. 28, the upper surface of the dielectric wall 133 is level with the upper surface of the gate electrode material 122, thus the dielectric wall 133 separates the replacement gate structure into two separate replacement gate structures 123A and 123B.

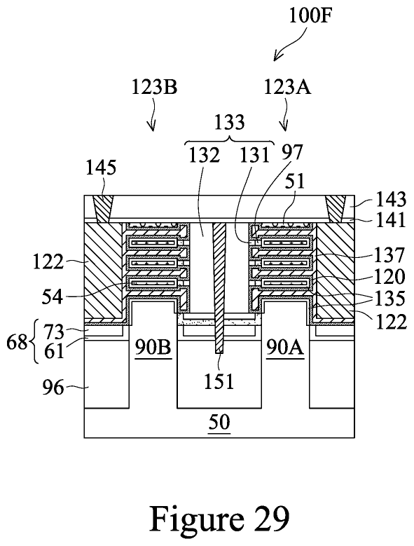

FIG. 29 is a cross-sectional view of a portion of an NSFET device 100F, in accordance with another embodiment. The NSFET device 100F is similar to the NSFET device 100E, but with a gate isolation structure 151. In the example of FIG. 29, the gate isolation structure 151 and the dielectric wall 133 together separate (e.g., cut) the replacement gate structure into replacement gate structures 123A and 123B. The cross-sectional view of FIG. 29 corresponds to that of FIG. 21B. Other cross-sectional views of the NSFET device 100F are the same as or similar to those of NSFET device 100.

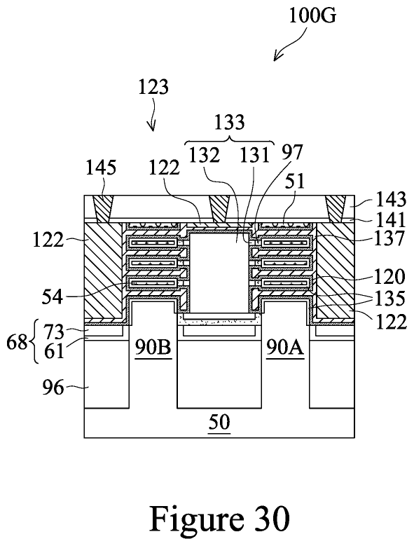

FIG. 30 is a cross-sectional view of a portion of an NSFET device 100G, in accordance with another embodiment. The NSFET device 100G is similar to the NSFET device 100E, but the dielectric wall 133 has a lower height such that the upper surface of the dielectric wall 133 is lower than the upper surface of the gate electrode material 122. Therefore, the dielectric wall 133 does not separate (e.g., cut) the replacement gate structure 123 into separate replacement gate structures. The cross-sectional view of FIG. 30 corresponds to that of FIG. 21B. Other cross-sectional views of the NSFET device 100G are the same as or similar to those of NSFET device 100.

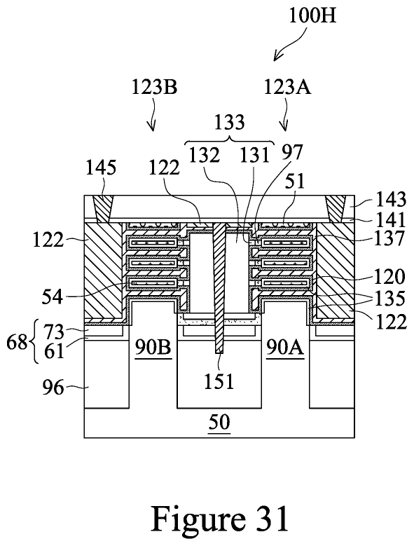

FIG. 31 is a cross-sectional view of a portion of an NSFET device 100H, in accordance with yet another embodiment. The NSFET device 100H is similar to the NSFET device 100G, but with a gate isolation structure 151. In the example of FIG. 31, the gate isolation structure 151 separates (e.g., cuts) the replacement gate structure into replacement gate structures 123A and 123B. The cross-sectional view of FIG. 31 corresponds to that of FIG. 21B. Other cross-sectional views of the NSFET device 100H are the same as or similar to those of NSFET device 100.

Advantages are achieved by the disclosed embodiments. For example, the use of the DOI process reduces intermixing between germanium and silicon, and provides significantly higher etching selectivity (e.g., >10000) between the disposable material 57 and the second semiconductor material 54. As a result, when the sacrificial material 57 is removed to form the nanostructures 54, there is little or no damage to the nanostructures. As another example, the disclosed STI protection structure 68 protects the STI regions 96 (e.g., portions under the dummy gates) during the removal of the sacrificial material 57, and as a result, loss of the STI region 96 is avoided or reduced. As another example, the dielectric wall 133 reduces gate-source capacitance, which in turn reduces RC delay and power consumption of the device formed. As yet another example, the dielectric layers 51 (e.g., the dummy sheets) not only helps to reduce gate-source capacitance, but also ensures uniform thickness of the work function material 137 to achieve uniform threshold voltage Vₜ for the device formed.

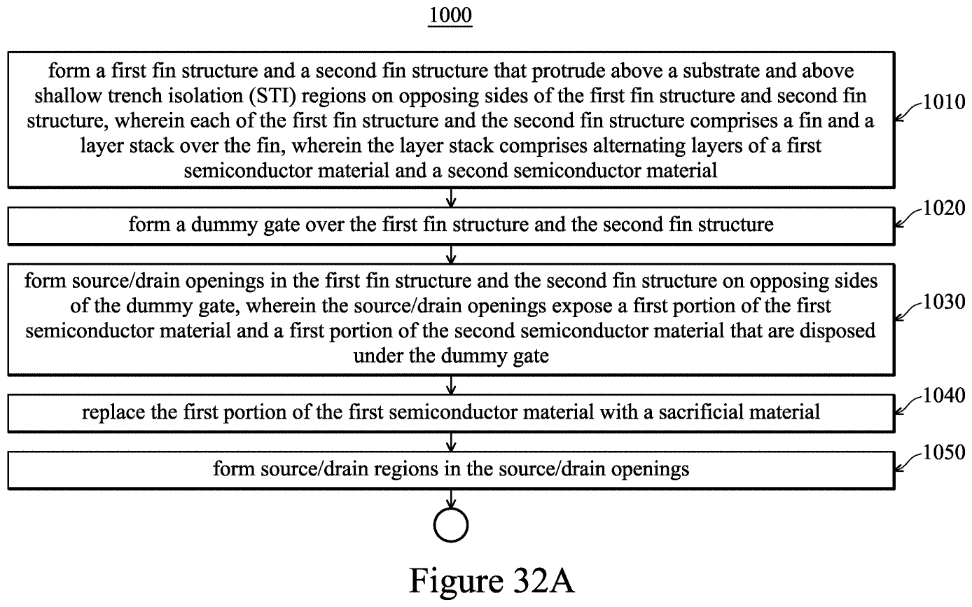

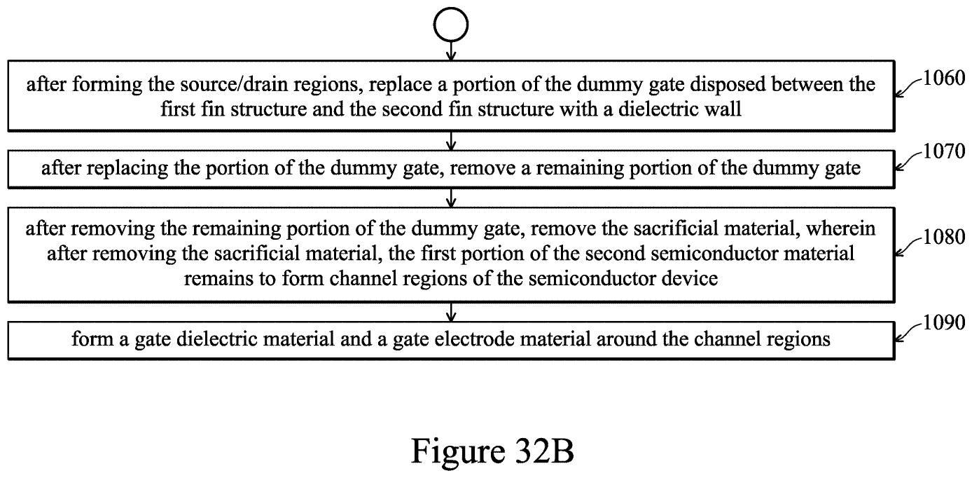

FIGS. 32A and 32B together illustrate a flow chart of a method 1000 of forming a semiconductor device, in accordance with some embodiments. It should be understood that the embodiment method shown in FIGS. 32A and 32B is merely an example of many possible embodiment methods. One of ordinary skill in the art would recognize many variations, alternatives, and modifications. For example, various steps as illustrated in FIGS. 32A and 32B may be added, removed, replaced, rearranged, or repeated.

Referring to FIGS. 32A and 32B, at block 1010, a first fin structure and a second fin structure that protrude above a substrate and above shallow trench isolation (STI) regions on opposing sides of the first fin structure and second fin structure are formed, wherein each of the first fin structure and the second fin structure comprises a fin and a layer stack over the fin, wherein the layer stack comprises alternating layers of a first semiconductor material and a second semiconductor material. At block 1020, a dummy gate is formed over the first fin structure and the second fin structure. At block 1030, source/drain openings are formed in the first fin structure and the second fin structure on opposing sides of the dummy gate, wherein the source/drain openings expose a first portion of the first semiconductor material and a first portion of the second semiconductor material that are disposed under the dummy gate. At block 1040, the first portion of the first semiconductor material is replaced with a sacrificial material. At block 1050, source/drain regions are formed in the source/drain openings. At block 1060, after forming the source/drain regions, a portion of the dummy gate disposed between the first fin structure and the second fin structure is replaced with a dielectric wall. At block 1070, after replacing the portion of the dummy gate, a remaining portion of the dummy gate is removed. At block 1080, after removing the remaining portion of the dummy gate, the sacrificial material is removed, wherein after removing the sacrificial material, the first portion of the second semiconductor material remains to form channel regions of the semiconductor device. At block 1090, a gate dielectric material and a gate electrode material are formed around the channel regions.

In an embodiment, a method of forming a semiconductor device comprises: forming a first fin structure and a second fin structure that protrude above a substrate and above shallow trench isolation (STI) regions on opposing sides of the first fin structure and second fin structure, wherein each of the first fin structure and the second fin structure comprises a fin and a layer stack over the fin, wherein the layer stack comprises alternating layers of a first semiconductor material and a second semiconductor material; forming a dummy gate over the first fin structure and the second fin structure; forming source/drain openings in the first fin structure and the second fin structure on opposing sides of the dummy gate, wherein the source/drain openings expose a first portion of the first semiconductor material and a first portion of the second semiconductor material that are disposed under the dummy gate; replacing the first portion of the first semiconductor material with a sacrificial material; forming source/drain regions in the source/drain openings; after forming the source/drain regions, replacing a portion of the dummy gate disposed between the first fin structure and the second fin structure with a dielectric wall; after replacing the portion of the dummy gate, removing a remaining portion of the dummy gate; after removing the remaining portion of the dummy gate, removing the sacrificial material, wherein after removing the sacrificial material, the first portion of the second semiconductor material remains to form channel regions of the semiconductor device; and forming a gate dielectric material and a gate electrode material around the channel regions. In an embodiment, the method further comprises, before forming the dummy gate, selectively forming an STI protection structure on upper surfaces of the STI regions, wherein the dummy gate is formed over the STI protection structure. In an embodiment, the method further comprises, after replacing the first portion of the first semiconductor material and before forming the source/drain regions: recessing end portions of the sacrificial material to form sidewall recesses; and forming inner spacers in the sidewall recesses. In an embodiment, the method further comprises, before forming the dummy gate, forming a dummy dielectric material over the first fin structure and the second fin structure, wherein removing the remaining portion of the dummy gate exposes the dummy dielectric material. In an embodiment, removing the sacrificial material comprises performing a first etching process, wherein the first etching process removes the sacrificial material and a first portion of the dummy dielectric material, wherein after the first etching process, a second portion of the dummy dielectric material remains between the channel regions and the dielectric wall. In an embodiment, the method further comprises, after performing the first etching process and before forming the gate dielectric material and the gate electrode material, performing a second etching process to remove the second portion of the dummy dielectric material. In an embodiment, the method further comprises, after removing the remaining portion of the dummy gate and before removing the sacrificial material: trimming the dielectric wall to reshape the dielectric wall, wherein before the trimming, the dielectric wall comprises a first portion over the first fin structure and the second fin structure and comprises a second portion between the first fin structure and the second fin structure, wherein the trimming removes the first portion of the dielectric wall. In an embodiment, the trimming further reduces a width of an upper portion of the second portion of the dielectric wall to form a protrusion, wherein a width of the protrusion decreases as the protrusion extends away from the substrate. In an embodiment, each of the first fin structure and the second fin structure further comprises a top dielectric material over the layer stack. In an embodiment, forming the gate dielectric material and the gate electrode material comprises forming the gate dielectric material and the gate electrode material around the channel regions and around the top dielectric material, wherein the method further comprises: recessing the gate dielectric material, the gate electrode material, and the top dielectric material such that the gate dielectric material, the gate electrode material, and the top dielectric material have a coplanar upper surface distal from the substrate. In an embodiment, the method further comprises forming a work function material between the gate dielectric material and the gate electrode material, wherein the work function material fills first spaces between the channel regions and fills second spaces between the channel regions and the top dielectric material. In an embodiment, the method further comprises forming a gate isolation structure that extends from an upper surface of the dielectric wall distal from the substrate, through the dielectric wall, and into the STI regions, wherein in a top view, the gate isolation structure extends parallel to the first fin structure and the second fin structure and intersects the dielectric wall, wherein the gate isolation structure extends between, and is spaced apart from, the source/drain regions.

In an embodiment, a method of forming a semiconductor device comprises: forming a first fin structure and a second fin structure that protrude above shallow trench isolation (STI) regions, wherein the STI regions are over a substrate and on opposing sides of the first fin structure and the second fin structure, wherein each of the first fin structure and the second fin structure comprises a fin and a layer stack over the fin, wherein the layer stack comprises alternating layers of a first semiconductor material and a second semiconductor material; forming a dummy gate structure over the first fin structure and the second fin structure, wherein the dummy gate structure comprises a dummy gate dielectric and a dummy gate, wherein a first portion of the first semiconductor material and a second portion of the second semiconductor material are disposed under the dummy gate structure; forming an interlayer dielectric (ILD) layer around the dummy gate structure; removing a first portion the dummy gate disposed between the first fin structure and the second fin structure to form an opening in the ILD layer, wherein the opening exposes a first portion of the dummy gate dielectric along an upper surface of the STI regions; filling the opening with a dielectric material to form a dielectric wall; after the filling, removing a remaining portion of the dummy gate; after removing the remaining portion of the dummy gate, removing a second portion of the dummy gate dielectric from a first sidewall of the first fin structure and removing a third portion of the dummy gate dielectric from a second sidewall of the second fin structure; after removing the second portion of the dummy gate dielectric and removing the third portion of the dummy gate dielectric, releasing the second portion of the second semiconductor material by removing one or more materials disposed between the second portion of the second semiconductor material, wherein after the releasing, the second portion of the second semiconductor material forms nanostructures; and forming a gate dielectric material, a work function material, and a gate electrode material around the nanostructures. In an embodiment, the method further comprises, after forming the dummy gate structure and before forming the ILD layer: forming source/drain openings in the first fin structure and the second fin structure on opposing sides of the dummy gate structure; after forming the source/drain openings, replacing the first portion of the first semiconductor material with a sacrificial material; and after replacing the first portion of the first semiconductor material, forming source/drain regions in the source/drain openings, wherein releasing the second portion of the second semiconductor material comprises removing the sacrificial material. In an embodiment, the method further comprises, after removing the remaining portion of the dummy gate and before removing the second portion and the third portion of the dummy gate dielectric, reshaping the dielectric wall by performing a trimming process, wherein the trimming process reduces a width of an upper portion of the dielectric wall, wherein a width of a lower portion of the dielectric wall remained unchanged before and after the trimming process. In an embodiment, each of the first fin structure and the second fin structure further comprises a top dielectric material over the layer stack, wherein the method further comprises, after forming the gate dielectric material, the work function material, and the gate electrode material: recessing the gate dielectric material, the work function material, and the gate electrode material such that the gate dielectric material, the work function material, the gate electrode material, and the top dielectric material have a coplanar upper surface distal from the substrate. In an embodiment, an upper surface of the dielectric wall distal from the substrate is closer to the substrate than the coplanar upper surface, wherein the method further comprises forming a gate isolation structure in the dielectric wall, wherein the gate isolation structure extends from the upper surface of the dielectric wall, through the dielectric wall, and into the STI regions.

In an embodiment, a semiconductor device comprises: a substrate; a first protrusion and a second protrusion that protrude above the substrate; a shallow trench isolation (STI) region between the first protrusion and the second protrusion; first source/drain regions over the first protrusion; first nanostructures over the first protrusion and between the first source/drain regions; second source/drain regions over the second protrusion; second nanostructures over the second protrusion and between the second source/drain regions; a dielectric structure over the STI region and between the first nanostructures and the second nanostructures; a gate dielectric material around the first nanostructures and the second nanostructures, wherein the gate dielectric material extends continuously from the first nanostructures to the dielectric structure, extends continuously from the second nanostructures to the dielectric structure, and extends along sidewalls of the dielectric structure; a work function material around the gate dielectric material, the first nanostructures, and the second nanostructures, wherein the work function material fills first spaces between the first nanostructures and fills second spaces between the first nanostructures and the dielectric structure; and a gate electrode material contacting and extending along the work function material. In an embodiment, the semiconductor device further comprises an STI protection structure contacting and extending along an upper surface of the STI region, wherein the dielectric structure is disposed over the STI protection structure. In an embodiment, the semiconductor device further comprises a first top dielectric layer over the first nanostructures and a second top dielectric layer over the second nanostructures, wherein the first top dielectric layer, the second top dielectric layer, the gate dielectric material, the work function material, and the gate electrode material have a coplanar upper surface distal from the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a first fin structure and a second fin structure that protrude above a substrate and above shallow trench isolation (STI) regions on opposing sides of the first fin structure and the second fin structure, wherein each of the first fin structure and the second fin structure comprises a fin, a layer stack over the fin, and a dummy sheet over the layer stack, wherein each of the layer stacks comprises alternating layers of a first semiconductor material and a second semiconductor material, and each of the dummy sheets comprises a dielectric material;
forming a dummy gate structure over the first fin structure and the second fin structure, wherein the dummy gate structure comprises a dummy gate dielectric and a dummy gate electrode, wherein the dummy gate structure overlies first portions of the first semiconductor material and second portions of the second semiconductor material;
forming gate spacers along opposing sidewalls of the dummy gate structure;
forming an interlayer dielectric (ILD) layer around the gate spacers and the dummy gate structure;
forming source/drain openings on opposing sides of the dummy gate structure in the first fin structure and in the second fin structure, wherein the source/drain openings expose sidewalls of the first portions of the first semiconductor material and sidewalls of the second portions of the second semiconductor material;
replacing the first portions of the first semiconductor material with a sacrificial material;
forming source/drain regions in the source/drain openings;
after forming the source/drain regions, replacing a portion of the dummy gate electrode disposed between the first fin structure and the second fin structure with a dielectric wall;
after replacing the portion of the dummy gate electrode, removing a remaining portion of the dummy gate electrode;
after removing the remaining portion of the dummy gate electrode, removing the sacrificial material and at least portions of the dummy gate dielectric, wherein after removing the sacrificial material, the second portions of the second semiconductor material remain to form channel layers of the semiconductor device;
forming a gate dielectric material around the channel layers and the dummy sheets;
forming a gate electrode material around the gate dielectric material, wherein the gate electrode material extends to an upper surface of the ILD layer distal from the substrate; and
after forming the gate electrode material, performing a planarization process on the gate dielectric material and the gate electrode material, wherein after the planarization process, upper surfaces of the dummy sheets distal from the substrate are level with an upper surface of the gate electrode material.

2. The method of claim 1, wherein the planarization process removes the gate spacers and the ILD layer.

3. The method of claim 2, wherein the planarization process further removes upper portions of the dummy sheets and a portion of the gate dielectric material disposed over the dummy sheets.

4. The method of claim 1, further comprising, after performing the planarization process:
forming an etch stop layer on the upper surfaces of the dummy sheets and the upper surface of the gate electrode material;
forming a dielectric layer over the etch stop layer; and
forming a gate contact plug in the dielectric layer and electrically coupled to the gate electrode material.

5. The method of claim 1, further comprising, after forming the gate dielectric material and before forming the gate electrode material, forming a work function material on the gate dielectric material and around the channel layers and the dummy sheets, wherein the work function material fills spaces between adjacent ones of the channel layers and between the dummy sheets and the channel layers.

6. The method of claim 1, further comprising, after removing the remaining portion of the dummy gate electrode and before removing the sacrificial material and at least portions of the dummy gate dielectric:
trimming the dielectric wall to reshape the dielectric wall, wherein before the trimming, the dielectric wall comprises a first portion extending above the first fin structure and the second fin structure and comprises a second portion disposed under the first portion of the dielectric wall and between the first fin structure and the second fin structure, wherein the trimming removes the first portion of the dielectric wall.

7. The method of claim 6, wherein the trimming further reduces a width of an upper portion of the second portion of the dielectric wall and forms curved sidewalls in the upper portion of the second portion of the dielectric wall, wherein a distance between the curved sidewalls decreases along a vertical direction extending away from the substrate, wherein after the trimming and before forming the gate electrode material, there are spaces laterally between the curved sidewalls and the channel layers.

8. The method of claim 7, wherein a first portion of the gate electrode material fills the spaces, wherein the method further comprises, after performing the planarization process, forming a gate contact over and electrically coupled to the first portion of the gate electrode material.

9. The method of claim 1, wherein removing the sacrificial material and at least portions of the dummy gate dielectric comprises performing a first etching process, wherein the first etching process removes the sacrificial material and a first portion of the dummy gate dielectric, wherein after the first etching process, a second portion of the dummy gate dielectric remains between the channel layers and the dielectric wall.

10. The method of claim 9, further comprising, after performing the first etching process and before forming the gate dielectric material, performing a second etching process to remove the second portion of the dummy gate dielectric.

11. The method of claim 1, further comprising, after performing the planarization process, forming a gate isolation structure that extends from an upper surface of the dielectric wall distal from the substrate, through the dielectric wall, and into the STI regions, wherein in a top view, the gate isolation structure extends parallel to the first fin structure and the second fin structure and intersects the dielectric wall.

12. A method of forming a semiconductor device, the method comprising:
forming a first fin structure and a second fin structure that protrude above shallow trench isolation (STI) regions, wherein the STI regions are over a substrate and on opposing sides of the first fin structure and the second fin structure, wherein each of the first fin structure and the second fin structure comprises a fin and a layer stack over the fin, wherein the layer stack comprises alternating layers of a first semiconductor material and a second semiconductor material;
selectively forming an STI protection structure on upper surfaces of the STI regions, wherein the STI protection structure is formed of one or more dielectric materials having etching selectivity relative to the STI regions;
forming a dummy gate structure over the first fin structure, the second fin structure, and the STI protection structure, wherein the dummy gate structure comprises a dummy gate dielectric and a dummy gate electrode, wherein first portions of the first semiconductor material and second portions of the second semiconductor material are disposed under the dummy gate structure;
forming gate spacers along opposing sidewalls of the dummy gate structure;
removing a first portion of the dummy gate electrode disposed between the first fin structure and the second fin structure to form an opening between the gate spacers, wherein the opening exposes first portions of the dummy gate dielectric disposed along a first sidewall of the first fin structure, a first sidewall of the second fin structure, and an upper surface of the STI protection structure;
forming a dielectric wall in the opening;
after forming the dielectric wall, removing a remaining portion of the dummy gate electrode;
after removing the remaining portion of the dummy gate electrode, removing second portions of the dummy gate dielectric from a second sidewall of the first fin structure and a second sidewall of the second fin structure;
after removing the second portions of the dummy gate dielectric, releasing the second portions of the second semiconductor material by removing one or more materials disposed between the second portions of the second semiconductor material, wherein after the releasing, the second portions of the second semiconductor material form nanostructures; and
forming a gate dielectric material and a gate electrode material around the nanostructures and the dielectric wall, wherein the gate dielectric material extends along an upper surface of the STI protection structure.

13. The method of claim 12, further comprising, after forming the gate dielectric material and the gate electrode material, performing a planarization process to recess the gate dielectric material and the gate electrode material, wherein the planarization process removes the gate spacers.

14. The method of claim 12, further comprising, after removing the remaining portion of the dummy gate electrode and before removing the second portions of the dummy gate dielectric, reshaping the dielectric wall by performing a trimming process, wherein the trimming process reduces a height of the dielectric wall, reduces a width of an upper portion of the dielectric wall, and removes at least a portion of the first portions of the dummy gate dielectric.

15. The method of claim 14, wherein after reshaping the dielectric wall, the upper portion of the dielectric wall has curved sidewalls, and a distance between the curved sidewalls decreases as the upper portion of the dielectric wall extends away from the substrate, wherein after the releasing, the upper portion of the dielectric wall extends further from the substrate than an uppermost nanostructure of the nanostructures distal from the substrate.

16. The method of claim 15, further comprising forming a gate isolation structure in the dielectric wall, wherein the gate isolation structure extends through the dielectric wall and into the STI regions, wherein in a top view, the gate isolation structure extends parallel to the first fin structure and the second fin structure and intersects the dielectric wall.

17. A semiconductor device comprising:
a substrate;
a first fin and a second fin that protrude above the substrate;
a shallow trench isolation (STI) region between the first fin and the second fin;
an STI protection structure contacting and extending along an upper surface of the STI region;
first source/drain regions over the first fin;
first nanostructures over the first fin and between the first source/drain regions;
a first dummy sheet over the first nanostructures;
second source/drain regions over the second fin;
second nanostructures over the second fin and between the second source/drain regions;
a second dummy sheet over the second nanostructures;
a dielectric wall over the STI protection structure and between the first nanostructures and the second nanostructures;
a gate dielectric material around the first nanostructures, the second nanostructures, and the dielectric wall; and
a gate electrode material around the gate dielectric material, wherein the first dummy sheet, the second dummy sheet, the gate dielectric material, and the gate electrode material have a coplanar upper surface distal from the substrate.

18. The semiconductor device of claim 17, wherein the dielectric wall has a lower portion and an upper portion over the lower portion, wherein the upper portion is narrower than the lower portion, wherein the upper portion of the dielectric wall has curved sidewalls, and a width between the curved sidewalls decreases as the upper portion of the dielectric wall extends away from the substrate.

19. The semiconductor device of claim 17, wherein the STI protection structure has a liner layer and a hard mask layer over the liner layer, wherein an upper surface of the liner layer extends along a bottom surface of the hard mask layer and sidewalls of the hard mask layer, wherein a lower surface of the liner layer extends along an upper surface of the STI region, a first sidewall of the first fin, and a second sidewall of the second fin.

20. The semiconductor device of claim 17, further comprising:
an etch stop layer (ESL) over the gate electrode material and the dielectric wall;
a dielectric layer over the ESL; and
a gate contact extending through the dielectric layer and the ESL, wherein the gate contact is electrically coupled to the gate electrode material.
